(19) United States
(12) Patent Application Publication
(10) Pub. No.: US 2025/0160163 A1
(43) Pub. Date: May 15, 2025

(54) DISPLAY DEVICE

(71) Applicant: Samsung Display Co., Ltd., Yongin-si (KR)

(72) Inventors: JUNWON CHOI, Yongin-si (KR); HYUN-CHOL BANG, Yongin-si (KR)

(73) Assignee: Samsung Display Co., Ltd., Yongin-si (KR)

(21) Appl. No.: 18/941,326

(22) Filed: Nov. 8, 2024

(30) Foreign Application Priority Data
Nov. 9, 2023 (KR) 10-2023-0154772

(51) Int. Cl. H10K 59/131; H01L 27/12; H10K 59/121; H10K 59/127; H10K 59/80

(52) U.S. Cl. CPC H10K 59/1315; H10D 86/441; H10D 86/60; H10K 59/1213; H10K 59/127; H10K 59/8722

(57) ABSTRACT

Disclosed is a display device which includes a first substrate including a fan-out wiring part, a second substrate facing the first substrate, and a sealant coupling the first and second substrates. The fan-out wiring part includes first and second fan-out lines, first and second connecting lines. The first fan-out line is disposed in a non-sealing area and includes a first gate wiring layer and a third gate wiring layer. The second fan-out line is disposed in the non-sealing area and includes a second gate wiring layer having a lower sheet resistance. The first connecting line is disposed in a sealing area and connected to the first fan-out line. The second connecting line is disposed in the sealing area and connected to the second fan-out line. Each of the first and second connecting lines includes one of the first and third gate wiring layers.

### CROSS-REFERENCE TO RELATED APPLICATION(S)

This application claims priority to and benefits of Korean Patent Application No. 10-2023-0154772 under 35 U.S.C. § 119, filed on Nov. 9, 2023, in the Korean Intellectual Property Office, the entire contents of which are incorporated herein by reference.

### BACKGROUND

### 1. Technical Field

Embodiments relate to a display device, and more particularly, relate to a display device having high resolution.

### 2. Description of the Related Art

Among display devices, an emissive display device displays an image using a light emitting diode that generates light by recombination of electrons and holes. The emissive display device has a high response speed and is driven with low power consumption.

The emissive display device includes a display panel in which pixels connected to data lines and scan lines are disposed. Each of the pixels includes a light emitting diode and a pixel circuit unit for controlling the amount of current flowing to the light emitting diode. In response to a data signal, the pixel circuit unit controls the amount of current flowing from a first drive voltage line to a second drive voltage line via the light emitting diode. At this time, light having a certain luminance is generated according to the amount of current flowing through the light emitting diode.

### SUMMARY

Embodiments provide a display device capable of improving signal delay due to wiring resistance while maintaining high resolution.

However, embodiments are not limited to those set forth herein. The above and other embodiments will become more apparent to one of ordinary skill in the art to which the disclosure pertains by referencing the detailed description of the disclosure given below.

According to an embodiment, a display device may include a first substrate including a plurality of pixels disposed in a display region and a fan-out wiring part disposed in a peripheral region adjacent to the display region, a second substrate facing the first substrate, and a sealant disposed in a sealing area of the peripheral region and that couples the first and second substrates.

The fan-out wiring part may include a first fan-out line, a second fan-out line, a first connecting line, and a second connecting line. The first fan-out line may be disposed in a first non-sealing area of the peripheral region and may include a first gate wiring layer and a third gate wiring layer disposed on the first gate wiring layer and connected to the first gate wiring layer, and the first non-sealing area does not overlap the sealant. The second fan-out line may be disposed in the first non-sealing area and may include a second gate wiring layer having a lower sheet resistance than sheet resistances of the first and third gate wiring layers. The first connecting line may be disposed in the sealing area and connected to the first fan-out line and may include one of the first gate wiring layer and the third gate wiring layer. The second connecting line may be disposed in the sealing area and connected to the second fan-out line and may include one of the first gate wiring layer and the third gate wiring layer.

The first, second, and third gate wiring layers may be disposed on different insulating layers, respectively.

Each of the first and third gate wiring layers may be a single-layer, and the second gate wiring layer may be a multi-layer in which a plurality of metal layers are sequentially stacked each other.

At least one of the plurality of metal layers may include aluminum, and the second gate wiring layer does not overlap the sealant in plan view.

The first and second connecting lines may include different gate wiring layers.

The first connecting line may include the first gate wiring layer, and the second connecting line may include the third gate wiring layer.

The display device may further include: a driver chip mounted on the first substrate, wherein the first substrate may further include data lines disposed in the display region and connected to the plurality of pixels, and the fan-out wiring part may connect the driver chip and the data lines.

The fan-out wiring part may further include: a third fan-out line disposed in a second non-sealing area of the peripheral region, the third fan-out line including the first gate wiring layer and the third gate wiring layer, the second non-sealing area not overlapping the sealant and disposed between the sealing area and the driver chip; and a fourth fan-out line disposed in the second non-sealing area, the fourth fan-out line including the second gate wiring layer.

The third fan-out line may be connected to the first connecting line, and the fourth fan-out line may be connected to the second connecting line.

The third fan-out line may be connected to the second connecting line, and the fourth fan-out line may be connected to the first connecting line.

The fan-out wiring part may further include: a third fan-out line disposed in a second non-sealing area of the peripheral region, the third fan-out line including a first data wiring layer, the second non-sealing area not overlapping the sealant and disposed between the sealing area and the driver chip; and a fourth fan-out line disposed in the second non-sealing area, the fourth fan-out line including a second data wiring layer.

The first data wiring layer and the second data wiring layer may be disposed on different insulating layers, respectively.

The first data wiring layer and the second data wiring layer may include a same material.

The first and second data wiring layers may have a lower sheet resistance than sheet resistances of the first, second, and third gate wiring layers, and the third and fourth fan-out lines may have a smaller width than widths of the first and second fan-out lines.

According to an embodiment, a display device may include a first substrate including a plurality of pixels disposed in a display region and a fan-out wiring part disposed in a peripheral region adjacent to the display region, a second substrate facing the first substrate, and a sealant disposed in a sealing area of the peripheral region and that couples the first and second substrates.

The fan-out wiring part may include first and second fan-out lines and first and second connecting lines. The first fan-out line may be disposed in a first non-sealing area of the peripheral region and may include one of a second gate wiring layer, a first data wiring layer, and a second data wiring layer, and the first non-sealing area does not overlap the sealant and is positioned between the sealing area and the display region. The second fan-out line may be disposed in the first non-sealing area and may include one of the second gate wiring layer, the first data wiring layer, and the second data wiring layer. The first connecting line may be disposed in the sealing area and connected to the first fan-out line and may include one of a first gate wiring layer and a third gate wiring layer. The second connecting line may be disposed in the sealing area and connected to the second fan-out line and may include at least one of the first gate wiring layer and the third gate wiring layer.

The first, second, and third gate wiring layers and the first and second data wiring layers are disposed on different insulating layers, and the second gate wiring layer and the first and second data wiring layers have a lower sheet resistance than sheet resistances of the first and third gate wiring layers.

The first and second connecting lines may include different gate wiring layers, respectively.

The first connecting line may include the first gate wiring layer, and the second connecting line may include the third gate wiring layer.

The display device may further include: a driver chip mounted on the first substrate, wherein the first substrate may further include data lines disposed in the display region and connected to the plurality of pixels, and the fan-out wiring part may connect the driver chip and the data lines.

The fan-out wiring part may further include: a third fan-out line disposed in a second non-sealing area of the peripheral region, the third fan-out line including one of the first and second data wiring layers, the second non-sealing area not overlapping the sealant and disposed between the sealing area and the driver chip; and a fourth fan-out line disposed in the second non-sealing area, the fourth fan-out line including one of the first and second data wiring layers.

Each of the first, second, third, and fourth fan-out lines may include the first data wiring layer, and the first, second, third, and fourth fan-out lines may have a smaller width than widths of the first and second connecting lines.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment.

FIG. 2 is an exploded schematic perspective view of the display device according to an embodiment.

FIG. 3 is a schematic plan view of a display panel according to an embodiment.

FIG. 4 is a schematic sectional view of the display panel taken along line I-I′ illustrated in FIG. 3.

FIG. 5 is a block diagram of the display device according to an embodiment.

FIG. 6A is a schematic diagram of an equivalent circuit of a pixel according to an embodiment.

FIG. 6B is a timing chart for explaining operation of the pixel according to an embodiment.

FIG. 7A is a timing chart for explaining the display device operating at a first drive frequency in a variable frequency mode according to an embodiment.

FIG. 7B is a timing chart for explaining the display device operating at a second drive frequency in the variable frequency mode according to an embodiment.

FIG. 8 is a schematic sectional view of the display panel according to an embodiment.

FIG. 9A is an enlarged schematic plan view illustrating a region BB illustrated in FIG. 3 according to an embodiment.

FIG. 9B is a schematic sectional view taken along line II-II′ illustrated in FIG. 9A according to an embodiment.

FIG. 9C is a schematic sectional view taken along line III-III′ illustrated in FIG. 9A according to an embodiment.

FIG. 9D is a schematic sectional view taken along line II-II′ illustrated in FIG. 9A according to an embodiment.

FIG. 9E is a schematic sectional view taken along line III-III′ illustrated in FIG. 9A according to an embodiment.

FIG. 10A is an enlarged schematic plan view illustrating the region BB illustrated in FIG. 3 according to an embodiment.

FIG. 10B is a schematic sectional view taken along line IV-IV′ illustrated in FIG. 10A according to an embodiment.

FIG. 10C is a schematic sectional view taken along line V-V′ illustrated in FIG. 10A according to an embodiment.

FIG. 10D is a schematic sectional view taken along line IV-IV′ illustrated in FIG. 10A according to an embodiment.

FIG. 10E is a schematic sectional view taken along line V-V′ illustrated in FIG. 10A according to an embodiment.

FIG. 11A is an enlarged schematic plan view illustrating the region BB illustrated in FIG. 3 according to an embodiment.

FIG. 11B is a schematic sectional view taken along line VI-VI′ illustrated in FIG. 11A according to an embodiment.

FIG. 11C is a schematic sectional view taken along line VII-VII′ illustrated in FIG. 11A according to an embodiment.

FIG. 12A is an enlarged schematic plan view illustrating the region BB illustrated in FIG. 3 according to an embodiment.

FIG. 12B is a schematic sectional view taken along line VIII-VIII′ illustrated in FIG. 12A according to an embodiment.

FIG. 12C is a schematic sectional view taken along line IX-IX′ illustrated in FIG. 12A according to an embodiment.

FIG. 13A is an enlarged schematic plan view illustrating the region BB illustrated in FIG. 3 according to an embodiment.

FIG. 13B is a schematic sectional view taken along line X-X′ illustrated in FIG. 13A according to an embodiment.

FIG. 14A is an enlarged schematic plan view illustrating the region BB illustrated in FIG. 3 according to an embodiment.

FIG. 14B is a schematic sectional view taken along line XI-XI′ illustrated in FIG. 14A according to an embodiment.

FIG. 15A is an enlarged schematic plan view illustrating the region BB illustrated in FIG. 3 according to an embodiment.

FIG. 15B is a schematic sectional view taken along line XII-XII′ illustrated in FIG. 15A according to an embodiment.

FIG. 15C is a schematic sectional view taken along line XIII-XIII′ illustrated in FIG. 15A according to an embodiment.

FIG. 16 is an enlarged schematic plan view illustrating the region BB illustrated in FIG. 3 according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described with reference to the accompanying drawings.

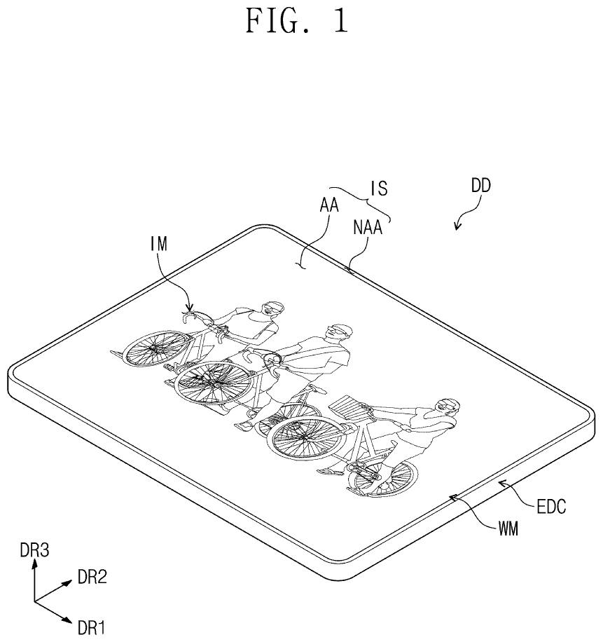

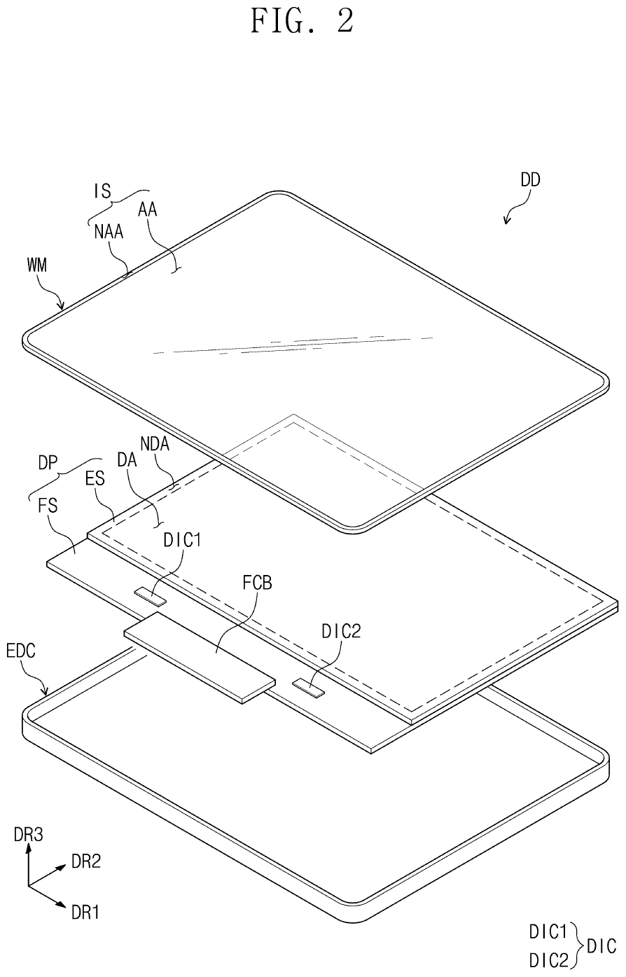

FIG. 1 is a schematic perspective view of a display device DD according to an embodiment, and FIG. 2 is an exploded schematic perspective view of the display device DD according to an embodiment.

Referring to FIGS. 1 and 2, the display device DD may be a device activated according to an electrical signal. The display device DD according to an embodiment may be a large display device such as a television, a monitor, or the like, or may be a small and medium-sized display device such as a mobile phone, a tablet computer, a notebook computer, a car navigation unit, a game machine, or the like. These devices are examples, and the display device DD may be implemented in other forms without departing from the spirit and scope of the disclosure. The display device DD may have a rectangular shape with long sides in a first direction DR1 and short sides in a second direction DR2 intersecting the first direction DR1. However, embodiments are not limited thereto, and the display device DD may have various shapes (e.g., an irregular shape). The display device DD may display an image IM in a third direction DR3 on a display surface IS parallel to the first direction DR1 and the second direction DR2. The display surface IS, on which the image IM is displayed, may correspond to the front surface of the display device DD.

In an embodiment, front surfaces (or upper surfaces) and rear surfaces (or lower surfaces) of members are defined based on the direction in which the image IM is displayed. The front surfaces and the rear surfaces may be opposite to each other in the third direction DR3, and the normal directions of the front surfaces and the rear surfaces may be parallel to the third direction DR3.

The separation distance between the front surface and the rear surface of the display device DD in the third direction DR3 may correspond to the thickness of the display device DD in the third direction DR3. For example, the directions indicated by the first to third directions DR1, DR2, and DR3 may be relative concepts and may be changed to other directions.

The display device DD may sense an external input applied from the outside. The external input may include various types of inputs provided from outside the display device DD. The display device DD according to an embodiment may sense a user's external input applied from the outside. The user's external input may be one of various types of external inputs, such as a part of the user's body, light, heat, gaze, and pressure, or a combination thereof. For example, the display device DD may sense the user's external input applied to the side surface or the rear surface of the display device DD according to the structure of the display device DD and is not limited to any one embodiment. In an embodiment, the external input may include an input by an input device (e.g., a stylus pen, an active pen, a touch pen, an electronic pen, an e-pen, or the like).

The display surface IS of the display device DD may be divided into an active region AA and an inactive region NAA. The active region AA may be a region on which the image IM is displayed. The user may visually recognize the image IM through the active region AA. In an embodiment, the active region AA is illustrated in a rounded quadrangular shape. However, this is an example, and the active region AA may have various shapes and is not limited to any one embodiment.

The inactive region NAA is adjacent to the active region AA. The inactive region NAA may have a certain color. The inactive region NAA may surround the active region AA. Accordingly, the shape of the active region AA may be substantially defined by the inactive region NAA. However, this is an example, and the inactive region NAA may be disposed adjacent to only one side of the active region AA, or may be omitted. The display device DD according to an embodiment may include various embodiments and is not limited to any one embodiment.

As illustrated in FIG. 2, the display device DD may include a display panel DP and a window WM disposed on the display panel DP. The display device DD may further include a functional layer (e.g., an input sensing layer or an anti-reflection layer) disposed between the display panel DP and the window WM.

The display panel DP according to an embodiment may be an emissive display panel. For example, the display panel DP may be an organic light emitting display panel, an inorganic light emitting display panel, or a quantum-dot light emitting display panel. An emissive layer of the organic light emitting display panel may include an organic luminescent material. An emissive layer of the inorganic light emitting display panel may include an inorganic luminescent material. An emissive layer of the quantum-dot light emitting display panel may include quantum dots and quantum rods.

The display panel DP may output the image IM, and the output image IM may be displayed through the display surface IS. The display panel DP may include a display region DA and a peripheral region NDA. The display region DA may be defined as a region where the image IM is output (e.g., a region where the image IM is displayed). According to an embodiment, the display region DA of the display panel DP may correspond to (or overlap) at least a portion of the active region AA.

The peripheral region NDA is adjacent to the display region DA. The peripheral region NDA may be a region where the image IM is not substantially displayed. For example, the peripheral region NDA may surround the display region DA. However, this is an example, and the peripheral region NDA may be defined in various shapes and is not limited to any one embodiment. According to an embodiment, the peripheral region NDA of the display panel DP may correspond to (or overlap) at least a portion of the inactive region NAA.

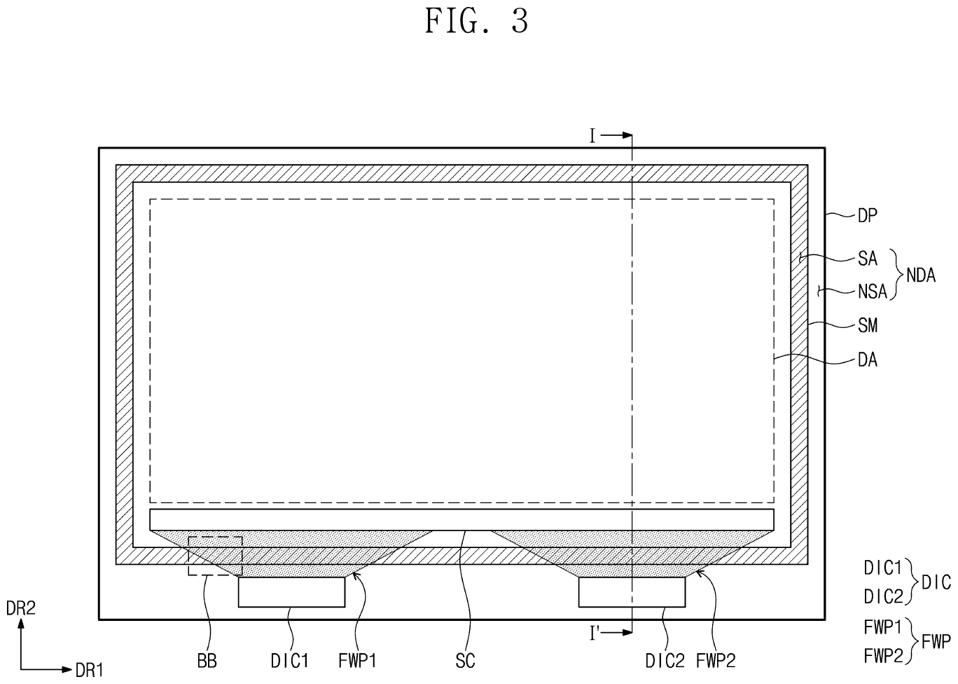

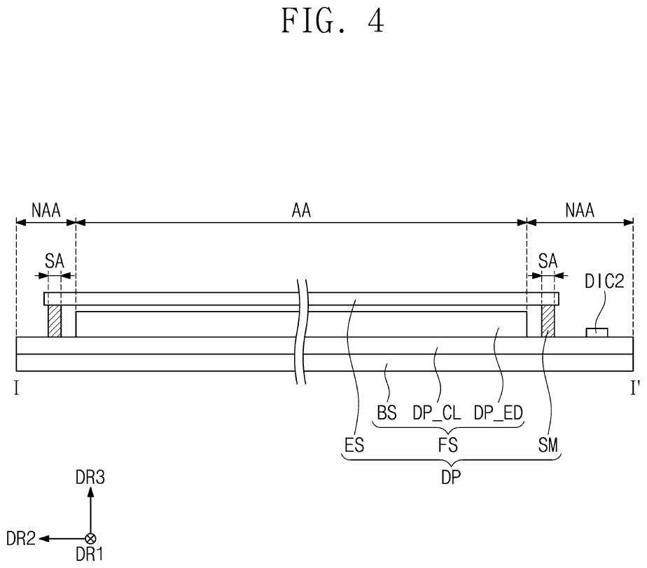

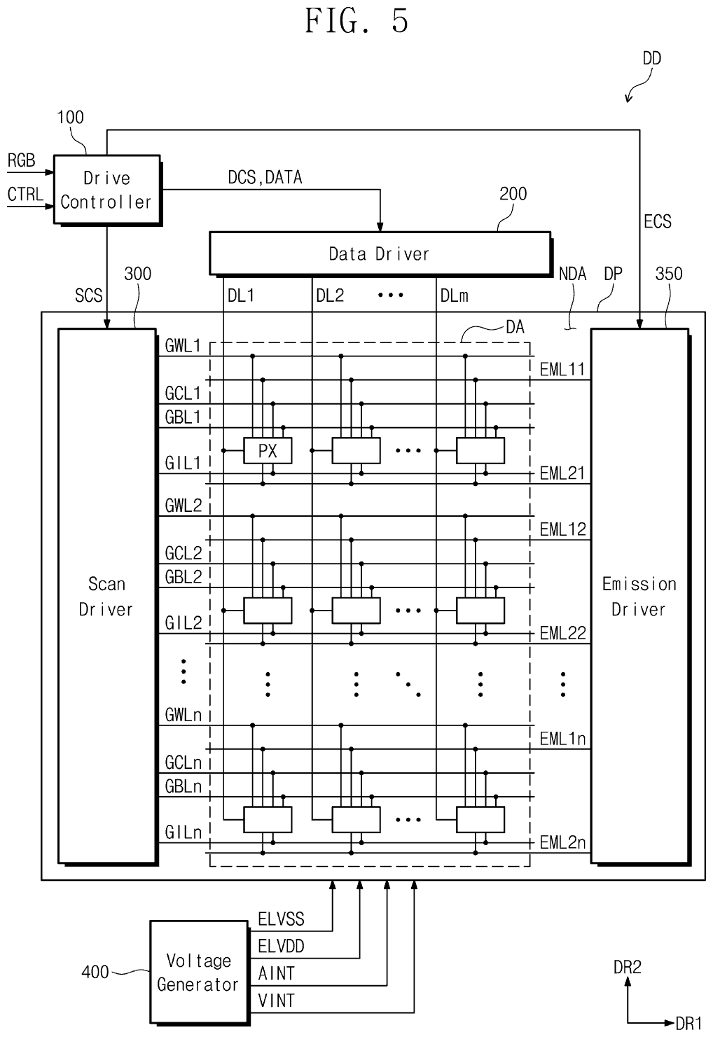

The display panel DP may be a rigid panel. The display panel DP may include a first substrate FS, a second substrate ES facing the first substrate FS, and a sealant SM (refer to FIG. 3) that couples the first substrate FS and the second substrate ES. The first substrate FS may include a base substrate BS (refer to FIG. 4) on which pixels PX (refer to FIG. 5) are formed. The second substrate ES may be an encapsulation substrate that is coupled to the sealant SM to seal the first substrate FS.

An input sensing layer may be disposed on the display panel DP and may sense an external input. The input sensing layer may be formed (e.g., directly formed) on the display panel DP (e.g., the second substrate ES) through a continuous process in case that the display panel DP is manufactured, or may be manufactured separately from the display panel DP by a separate process and then may be fixed to the upper surface of the display panel DP by an internal adhesive film.

The window WM may be formed of a transparent material through which the image IM (refer to FIG. 1) is able to be output. For example, the window WM may be formed of glass, sapphire, plastic, or the like. Although the window WM is illustrated as a single layer, the window WM is not limited thereto and may include a plurality of layers.

For example, the above-described inactive region NAA of the display device DD may be substantially provided as a region formed by printing a material having a certain color on a region of the window WM. In an embodiment, the window WM may include a light blocking pattern for defining the inactive region NAA. The light blocking pattern may be a colored organic film and may be formed by, for example, a coating process.

An anti-reflection layer may be additionally disposed between the window WM and the display panel DP. The anti-reflection layer may decrease the reflectance of external light incident from above the window WM. The anti-reflection layer according to an embodiment may include a phase retarder and a polarizer. The phase retarder may be of a film type or a liquid-crystal coating type and may include a λ/2 phase retarder and/or a λ/4 phase retarder. The polarizer may also be of a film type or a liquid-crystal coating type. The polarizer of a film type may include a stretchable synthetic resin film, and the polarizer of a liquid-crystal coating type may include liquid crystals arranged in a certain arrangement. The phase retarder and the polarizer may be implemented as a single polarizer film.

In an embodiment, the anti-reflection layer may include color filters. The arrangement of the color filters may be determined in consideration of the colors of light generated by the pixels PX (refer to FIG. 5) included in the display panel DP. For example, the anti-reflection layer may further include a light blocking pattern disposed between the color filters.

The display device DD may further include at least one driver chip DIC and a flexible film FCB electrically connected to the at least one driver chip DIC. Although two driver chips (hereinafter, referred to as the first and second driver chips DIC1 and DIC2) are illustrated in FIG. 2, the number of driver chips is not limited thereto. In an embodiment, the first and second driver chips DIC1 and DIC2 may be mounted on the display panel DP. For example, the first and second driver chips DIC1 and DIC2 may be mounted on the peripheral region NDA of the display panel DP. In an embodiment, a data driver 200 (refer to FIG. 5) may be implemented as the first and second driver chips DIC1 and DIC2. Although FIG. 2 illustrates an embodiment in which the first and second driver chips DIC1 and DIC2 are mounted on the display panel DP, embodiments are not limited thereto. For example, the first and second driver chips DIC1 and DIC2 may be mounted on the flexible film FCB.

The flexible film FCB may be attached to an end portion of the display panel DP. The flexible film FCB may be electrically connected to the first and second driver chips DIC1 and DIC2 and may supply signals required for operation of the first and second driver chips DIC1 and DIC2. The display device DD may further include at least one circuit board coupled to the flexible film FCB. A drive controller 100 (refer to FIG. 5) and a voltage generator 400 (refer to FIG. 5) may be disposed on the circuit board.

The display device DD may further include a housing EDC accommodating the display panel DP. The housing EDC may be coupled to the window WM to define the exterior of the display device DD. The housing EDC may protect components accommodated in the housing EDC by absorbing impact applied from the outside and preventing infiltration of foreign matter/moisture into the display panel DP. In an embodiment, the housing EDC may be provided in a form in which multiple receiving members are combined.

The display device DD according to an embodiment may further include an electronic module including various functional modules for operating the display panel DP, a power supply module (e.g., a battery) that supplies power required for overall operation of the display device DD, and a bracket that is coupled to the display panel DP and/or the housing EDC and that divides the inner space of the display device DD.

FIG. 3 is a schematic plan view of the display panel DP according to an embodiment, and FIG. 4 is a schematic sectional view of the display panel DP taken along line I-I′ illustrated in FIG. 3 according to an embodiment.

Referring to FIGS. 3 and 4, the display panel DP may include the first substrate FS, the second substrate ES, and the sealant SM. The first substrate FS may include the base substrate BS, a circuit layer DP_CL, and a display element layer DP_ED.

The base substrate BS may include a plastic substrate, a glass substrate, a metal substrate, or an organic/inorganic composite substrate. According to an embodiment, the base substrate BS may include at least one plastic film.

The circuit layer DP_CL may be disposed on the base substrate BS. The circuit layer DP_CL may include at least one insulating layer and a circuit element. The insulating layer may include at least one inorganic layer and at least one organic layer. The circuit element may include a signal line and a pixel circuit unit. The formation of the circuit layer DP_CL may include a first step of forming an insulating layer, a semiconductor layer, and a conductive layer by coating, deposition, or the like, and a second step of patterning the insulating layer, the semiconductor layer, and the conductive layer by a photolithography process.

The display element layer DP_ED may include light emitting elements and a pixel defining layer. The display element layer DP_ED may be disposed in the display region DA of the display panel DP.

The second substrate ES may be disposed to face the base substrate BS and may cover the display element layer DP_ED. The sealant SM may be disposed between the second substrate ES and the base substrate BS. The sealant SM may be disposed in the peripheral region NDA of the display panel DP. The second substrate ES and the base substrate BS may be coupled to each other by the sealant SM. The sealant SM may have a closed-loop shape surrounding the display region DA and may seal the space between the second substrate ES and the base substrate BS.

An area of the peripheral region NDA where the sealant SM is disposed may be referred to as a sealing area SA, and an area of the peripheral region NDA where the sealant SM is not disposed may be referred to as a non-sealing area NSA.

In the non-sealing area NSA positioned outside the sealant SM, the first and second driver chips DIC1 and DIC2 may be disposed on the first substrate FS.

The first and second driver chips DIC1 and DIC2 may supply data signals to data lines DL1 to DLm (refer to FIG. 5) positioned in the display region DA. In an embodiment, the display panel DP may further include a selection circuit SC positioned between the first and second driver chips DIC1 and DIC2 and the data lines DL1 to DLm. The selection circuit SC may alternately apply the data signals output from the first and second driver chips DIC1 and DIC2 to a first group and a second group into which the data lines DL1 and DLm are divided. In another example, the selection circuit SC may be omitted.

A fan-out wiring part FWP may be disposed between the display region DA of the display panel DP and the first and second driver chips DIC1 and DIC2. The fan-out wiring part FWP may be disposed in the peripheral region NDA so as to be adjacent to the first and second driver chips DIC1 and DIC2. In case that the selection circuit SC is disposed, the fan-out wiring part FWP may be disposed (or provided) between the selection circuit SC and the first and second driver chips DIC1 and DIC2. In another example, in case that the selection circuit SC is omitted, the fan-out wiring part FWP may be disposed (or provided) between the display region DA and the first and second driver chips DIC1 and DIC2.

In an embodiment, the fan-out wiring part FWP may include a first fan-out wiring part FWP1 and a second fan-out wiring part FWP2. The first fan-out wiring part FWP1 may be positioned between the selection circuit SC and the first driver chip DIC1, and the second fan-out wiring part FWP2 may be positioned between the selection circuit SC and the second driver chip DIC2. The width of each of the first and second fan-out wiring parts FWP1 and FWP2 may be gradually increased as being closer to the selection circuit SC (or the display region DA) from the corresponding driver chip DIC1 or DIC2.

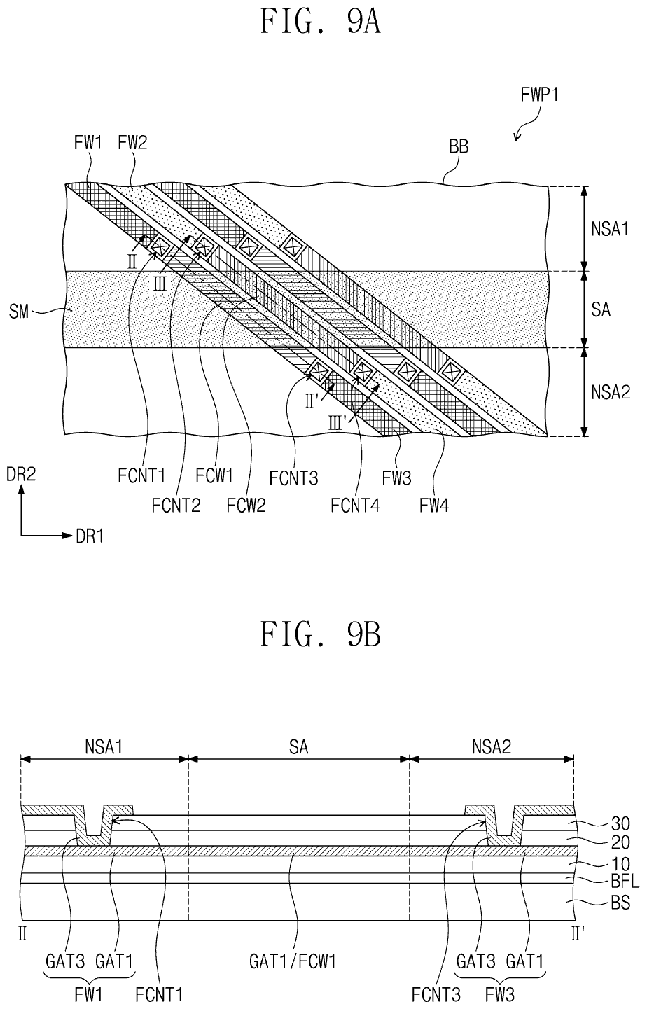

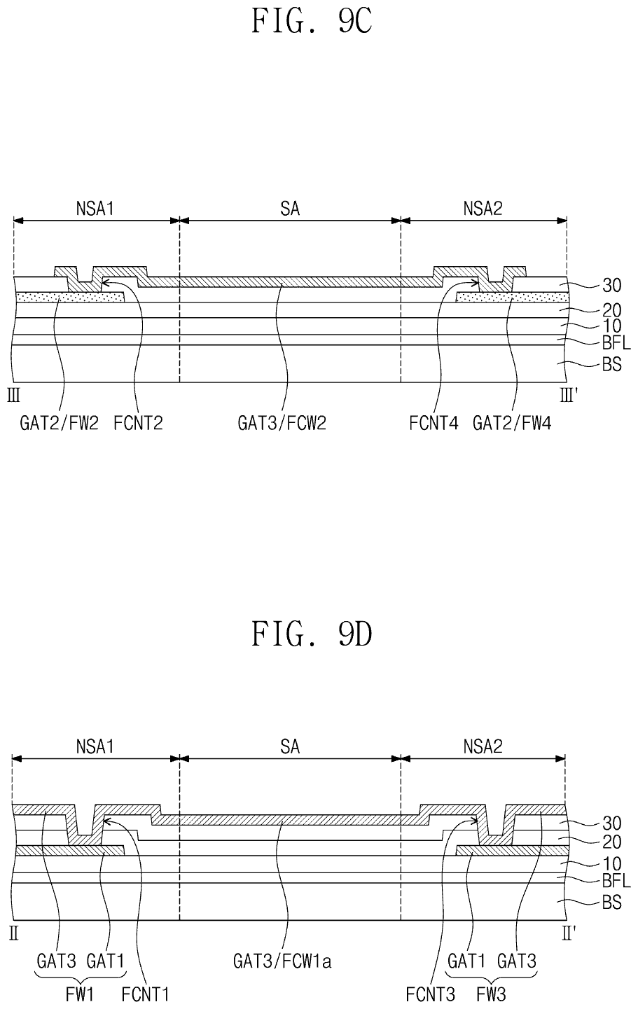

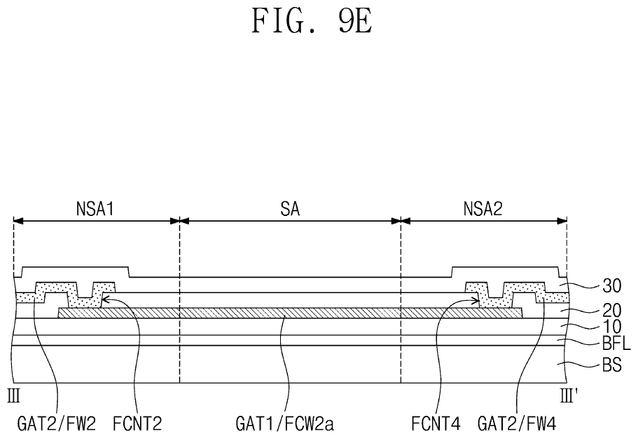

The first and second fan-out wiring parts FWP1 and FWP2 may overlap (e.g., partially overlap) the sealing area SA in plan view (or when viewed from above the plane). The fan-out wiring part FWP will be described below in detail with reference to FIGS. 9A to 9E, 10A to 10E, 11A to 11C, 12A to 12C, 13A, 13B, 14A, 14B, 15A to 15C, and 16.

FIG. 5 is a block diagram of the display device DD according to an embodiment.

Referring to FIG. 5, the display device DD may be activated according to an electrical signal and may display an image. The display device DD may be applied to an electronic device such as a smart watch, a tablet computer, a notebook computer, a computer, a smart television, or the like.

The display device DD may include the display panel DP, the drive controller 100, the data driver 200, a scan driver 300, an emission driver 350, and the voltage generator 400.

The drive controller 100 may receive an image signal RGB and a control signal CTRL. The drive controller 100 may generate image data DATA by converting the data format of the image signal RGB according to the specification of an interface with the data driver 200. The drive controller 100 may output a scan control signal SCS, a data control signal DCS, and an emission drive control signal ECS.

The data driver 200 may receive the data control signal DCS and the image data DATA from the drive controller 100. The data driver 200 may convert the image data DATA into data signals and may output the data signals to the data lines DL1 to DLm. The data signals may be analog data voltages corresponding to gray level values of the image data DATA.

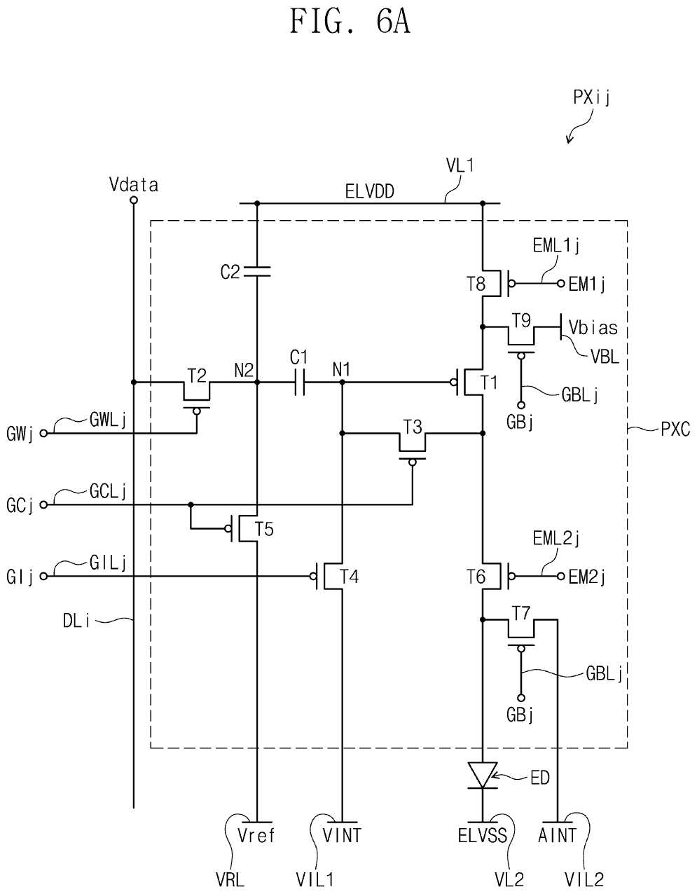

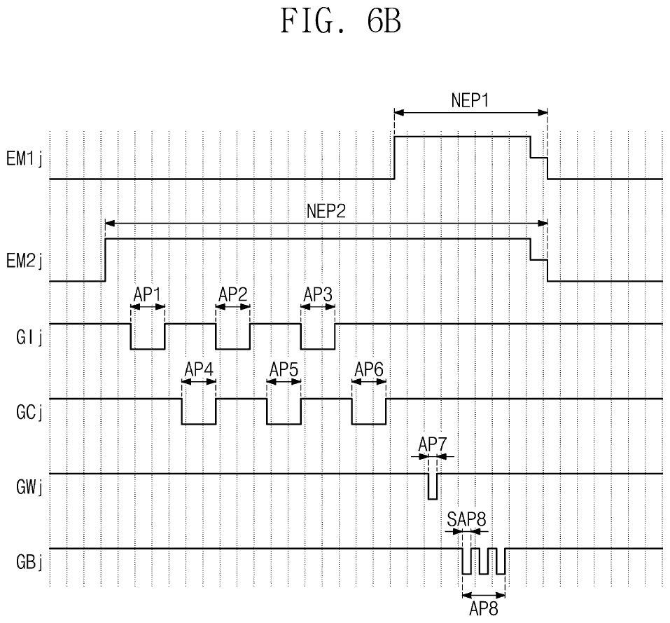

The voltage generator 400 may generate voltages required for operation of the display panel DP. In an embodiment, the voltage generator 400 may generate a first drive voltage ELVDD, a second drive voltage ELVSS, a first initialization voltage VINT, and a second initialization voltage AINT. The first initialization voltage VINT may have a voltage level different from that of the second initialization voltage AINT. The voltage generator 400 may generate voltages required for operation of the display panel DP. In an embodiment, the voltage generator 400 may additionally generate a reference voltage Vref (refer to FIG. 6A) and a bias voltage Vbias (refer to FIG. 6A) that are supplied to the display panel DP.

The scan driver 300 may receive the scan control signal SCS from the drive controller 100. The scan control signal SCS may include a start signal to start operation of the scan driver 300 and clock signals. The scan driver 300 may generate scan signals and may sequentially output the scan signals to scan lines that will be described below. The emission driver 350 may output emission control signals to emission control lines EML11 to EML1n and EML21 to EML2n, which will be described below, in response to the emission drive control signal ECS from the drive controller 100. In an embodiment, the scan driver 300 and the emission driver 350 may be integrated into a single circuit.

The scan driver 300 may output initialization scan signals to initialization scan lines GIL1 to GILn of the display panel DP and may output compensation scan signals to compensation scan lines GCL1 to GCLn of the display panel DP. The scan driver 300 may output write scan signals to write scan lines GWL1 to GWLn of the display panel DP and may output black scan signals to black scan lines GBL1 to GBLn of the display panel DP.

The display panel DP may include the initialization scan lines GIL1 to GILn, the compensation scan lines GCL1 to GCLn, the write scan lines GWL1 to GWLn, the black scan lines GBL1 to GBLn, the emission control lines EML11 to EML1n and EML21 to EML2n, the data lines DL1 to DLm, and the pixels PX. The display panel DP may have the display region DA and the peripheral region NDA defined therein. The initialization scan lines GIL1 to GILn, the compensation scan lines GCL1 to GCLn, the write scan lines GWL1 to GWLn, the black scan lines GBL1 to GBLn, the emission control lines EML11 to EML1n and EML21 to EML2n, the data lines DL1 to DLm, and the pixels PX may be disposed in the display region DA. The initialization scan lines GIL1 to GILn, the compensation scan lines GCL1 to GCLn, the write scan lines GWL1 to GWLn, the black scan lines GBL1 to GBLn, and the emission control lines EML11 to EML1n and EML21 to EML2n may extend in the first direction DR1 and may be arranged in the second direction DR2 so as to be spaced apart from each other. The data lines DL1 to DLm may extend in the second direction DR2 and may be arranged in the first direction DR1 so as to be spaced apart from each other.

The scan driver 300 and the emission driver 350 may be disposed in the peripheral region NDA of the display panel DP. In an embodiment, the scan driver 300 may be disposed adjacent to a first side of the display region DA, and the emission driver 350 may be disposed adjacent to a second side of the display region DA that faces away from the first side. Although the scan driver 300 and the emission driver 350 are disposed adjacent to the opposite sides of the display region DA in the embodiment illustrated in FIG. 5, embodiments are not limited thereto. For example, the scan driver 300 and the emission driver 350 may be disposed adjacent to one of the first and second sides of the display panel DP.

The pixels PX may be electrically connected to the initialization scan lines GIL1 to GILn, the compensation scan lines GCL1 to GCLn, the write scan lines GWL1 to GWLn, the black scan lines GBL1 to GBLn, the emission control lines EML11 to EML1n and EML21 to EML2n, and the data lines DL1 to DLm, respectively. Each of the pixels PX may be electrically connected to four scan lines and two emission control lines. For example, as illustrated in FIG. 5, the first row of pixels may be connected to the first initialization scan line GIL1, the first compensation scan line GCL1, the first write scan line GWL1, the first black scan line GBL1, the first-first emission control line EML11, and the second-first emission control line EML21. For example, the second row of pixels may be connected to the second initialization scan line GIL2, the second compensation scan line GCL2, the second write scan line GWL2, the second black scan line GBL2, the first-second emission control line EML12, and the second-second emission control line EML22. However, embodiments are not limited thereto, the numbers of scan lines and emission control lines connected to each pixel PX may be varied.

Each of the pixels PX may include a light emitting element ED (refer to FIG. 6A) and a pixel circuit unit PXC (refer to FIG. 6A) that controls light emission of the light emitting element ED. The pixel circuit unit PXC may include one or more transistors and one or more capacitors. The scan driver 300 and the emission driver 350 may be formed (e.g., directly formed) in the peripheral region NDA of the display panel DP by the same process as that used for the transistors of the pixel circuit unit PXC.

Each of the pixels PX may receive the first drive voltage ELVDD, the second drive voltage ELVSS, and the first and second initialization voltages VINT and AINT from the voltage generator 400. In another example, each of the pixels PX may additionally receive the bias voltage Vbias from the voltage generator 400.

FIG. 6A is a schematic diagram of an equivalent circuit of a pixel PX according to an embodiment, and FIG. 6B is a timing chart for explaining operation of the pixel PX according to an embodiment.

The pixels PX illustrated in FIG. 5 may have the same configuration. Accordingly, the configuration of a pixel PXij among the pixels PX will be described with reference to FIG. 6A, and descriptions of the configurations of the remaining pixels will be omitted for descriptive convenience.

Referring to FIG. 6A, the pixel PXij may be connected to a j-th initialization scan line GILj among the initialization scan lines GIL1 to GILn, a j-th compensation scan line GCLj among the compensation scan lines GCL1 to GCLn, a j-th write scan line GWLj among the write scan lines GWL1 to GWLn, and a j-th black scan line GBLj among the black scan lines GBL1 to GBLn illustrated in FIG. 5. For example, the pixel PXij may be connected to an i-th data line DLi among the data lines DL1 to DLm and a (1-j)-th emission control line EML1j and a (2-j)-th emission control line EML2j among the emission control lines EML11 to EML1n and EML21 to EML2n illustrated in FIG. 5.

Referring to FIG. 6A, the pixel PXij according to an embodiment may include the pixel circuit unit PXC and the light emitting element ED. In an embodiment, the pixel circuit unit PXC may include nine transistors and two capacitors. Hereinafter, the nine transistors are referred to as first to ninth transistors T1, T2, T3, T4, T5, T6, T7, T8, and T9, and the two capacitors are referred to as first and second capacitors C1 and C2.

In an embodiment, each of the first to ninth transistors T1 to T9 is a P-type transistor having a low-temperature polycrystalline silicon (LTPS) semiconductor layer. In another example, each of the first to ninth transistors T1 to T9 may be an N-type transistor. In another example, at least one of the first to ninth transistors T1 to T9 may be an N-type transistor, and the remaining transistors may be P-type transistors. At least one of the first to ninth transistors T1 to T9 may be a transistor having an oxide semiconductor layer. For example, some of the first to ninth transistors T1 to T9 may be oxide semiconductor transistors, and the remaining transistors may be LTPS transistors.

The circuit configuration of the pixel PXij is not limited to the circuit configuration illustrated in FIG. 6A. The pixel PXij illustrated in FIG. 6A is an example, and various changes and modifications may be made to the circuit configuration of the pixel PXij.

The j-th initialization scan line GILj may supply a j-th initialization scan signal GIj to the pixel PXij. The j-th write scan line GWLj may supply a j-th write scan signal GWj to the pixel PXij, and the j-th compensation scan line GCLj may supply a j-th compensation scan signal GCj to the pixel PXij. The (1-j)th emission control line EML1j may supply a (1-j)th emission control signal EM1j to the pixel PXij, the (2-j)th emission control line EML2j may supply a (2-j)th emission control signal EM2j to the pixel PXij, and the i-th data line DLi may transfer an i-th data voltage Vdata to the pixel PXij. The i-th data voltage Vdata may have a voltage level corresponding to the image data DATA input to the data driver 200 (refer to FIG. 5) of the display device DD (refer to FIG. 5).

The pixel PXij may be connected to a first drive voltage line VL1, a second drive voltage line VL2, a first initialization voltage line VIL1, a second initialization voltage line VIL2, a reference voltage line VRL, and a bias voltage line VBL.

The first drive voltage line VL1 may transfer the first drive voltage ELVDD supplied from the voltage generator 400 illustrated in FIG. 5 to the pixel PXij, and the second drive voltage line VL2 may transfer the second drive voltage ELVSS supplied from the voltage generator 400 to the pixel PXij. The first initialization voltage line VIL1 and the second initialization voltage line VIL2 may receive the first initialization voltage VINT and the second initialization voltage AINT from the voltage generator 400 and transfer the first initialization voltage VINT and the second initialization voltage AINT to the pixel PXij. The reference voltage line VRL may receive the reference voltage Vref from the voltage generator 400 and may transfer the reference voltage Vref to the pixel PXij. The bias voltage line VBL may receive the bias voltage Vbias from the voltage generator 400 (refer to FIG. 5) and may transfer the bias voltage Vbias to the pixel PXij.

Each of the first to ninth transistors T1 to T9 may include an input electrode (e.g., a source electrode), an output electrode (e.g., a drain electrode), and a control electrode (e.g., a gate electrode). In the description, for descriptive convenience, the input electrode, the output electrode, and the control electrode may be referred to as the first electrode, the second electrode, and the third electrode.

The first transistor T1 (referred to as a drive transistor) may be disposed (or provided) between the first drive voltage line VL1 and the light emitting element ED. For example, the first transistor T1 may include the first electrode electrically connected to the first drive voltage line VL1, the second electrode electrically connected to the light emitting element ED, and the third electrode connected to a first node N1. The first transistor T1 may receive the first drive voltage ELVDD through the first drive voltage line VL1. The first electrode of the first transistor T1 may be connected to the first drive voltage line VL1 via the eighth transistor T8, and the second electrode of the first transistor T1 may be electrically connected to an anode of the light emitting element ED via the sixth transistor T6.

The second transistor T2 may be connected between the i-th data line DLi and a second node N2. For example, the second transistor T2 may include the first electrode connected to the i-th data line DLi, the second electrode connected to the second node N2, and the third electrode that receives the j-th write scan signal GWj through the j-th write scan line GWLj. During a data write period AP7 (refer to FIG. 6B), the second transistor T2 may be turned on in response to the j-th write scan signal GWj provided to the j-th write scan line GWLj. The i-th data line DLi and the second node N2 may be electrically connected by the turned-on second transistor T2, and the i-th data voltage Vdata applied to the i-th data line DLi may be applied to the second node N2 through the turned-on second transistor T2.

The first capacitor C1 may be connected between the first node N1 and the second node N2, and the second capacitor C2 may be connected between the second node N2 and the first drive voltage line VL1. The first capacitor C1 may include a first electrode electrically connected to the first node N1 and a second electrode electrically connected to the second node N2. The second capacitor C2 may include a first electrode electrically connected to the first drive voltage line VL1 and a second electrode electrically connected to the second node N2.

The third transistor T3 may be connected between the second electrode of the first transistor T1 and the third electrode of the first transistor T1. For example, the third transistor T3 may include the first electrode electrically connected to the second electrode of the first transistor T1, the second electrode electrically connected to the first node N1, and the third electrode that receives the j-th compensation scan signal GCj through the j-th compensation scan line GCLj. During compensation periods AP4, AP5, and AP6 (refer to FIG. 6B), the third transistor T3 may be turned on in response to the j-th compensation scan signal GCj provided to the j-th compensation scan line GCLj. During the compensation periods AP4, AP5, and AP6, the first transistor T1 may be connected in a diode form (or diode-connected) by the turned-on third transistor T3.

The fourth transistor T4 (referred to as a first initialization transistor) may be electrically connected between the first node N1 and the first initialization voltage line VIL1. For example, the fourth transistor T4 may include the first electrode electrically connected to the first node N1, the second electrode electrically connected to the first initialization voltage line VIL1, and the third electrode that receives the j-th initialization scan signal GIj through the j-th initialization scan line GILj. The first initialization voltage VINT may be applied to the first initialization voltage line VIL1. During initialization periods AP1, AP2, and AP3 (refer to FIG. 6B), the fourth transistor T4 may be turned on in response to the j-th initialization scan signal GIj provided to the j-th initialization scan line GILj. During the initialization periods AP1, AP2, and AP3, the first node N1 may be initialized to the first initialization voltage VINT by the turned-on fourth transistor T4.

The fifth transistor T5 may be electrically connected between the second node N2 and the reference voltage line VRL. The reference voltage line VRL may receive the reference voltage Vref from the voltage generator 400 illustrated in FIG. 5 and may supply the reference voltage Vref to the pixel PXij. The reference voltage Vref may have a lower voltage level than the first drive voltage ELVDD. The fifth transistor T5 may include the first electrode connected to the reference voltage line VRL, the second electrode electrically connected to the second node N2, and the third electrode that receives the j-th compensation scan signal GCj through the j-th compensation scan line GCLj. During the compensation periods AP4, AP5, and AP6, the fifth transistor T5 may be turned on in response to the j-th compensation scan signal GCj provided to the j-th compensation scan line GCLj. The reference voltage line VRL and the second node N2 may be electrically connected by the turned-on fifth transistor T5. For example, during the compensation periods AP4, AP5, and AP6, the reference voltage Vref may be applied to the second node N2.

In an embodiment, the third electrodes of the third and fifth transistors T3 and T5 may be commonly connected to the j-th compensation scan line GCLj. However, embodiments are not limited thereto. For example, the third electrode of the third transistor T3 and the third electrode of the fifth transistor T5 may be connected to different scan lines and may receive different scan signals.

The sixth transistor T6 (referred to as a first emission control transistor) may be connected between the second electrode of the first transistor T1 and the anode of the light emitting element ED. For example, the sixth transistor T6 may include the first electrode connected to the second electrode of the first transistor T1, the second electrode electrically connected to the anode of the light emitting element ED, and the third electrode electrically connected to the (2-j)th emission control line EML2j. During a second non-emission period NEP2, the sixth transistor T6 may be turned on by the (2-j)th emission control signal EM2j provided to the (2-j)th emission control line EML2j.

The seventh transistor T7 (referred to as a second initialization transistor) may be connected between the second initialization voltage line VIL2 and the anode of the light emitting element ED. The seventh transistor T7 may include the first electrode connected to the anode of the light emitting element ED, the second electrode connected to the second initialization voltage line VIL2, and the third electrode that receives the j-th black scan signal GBj (referred to as an initialization control signal) through the j-th black scan line GBLj. The second initialization voltage AINT may be applied to the second initialization voltage line VIL2. In an embodiment, the second initialization voltage AINT may have a voltage level different from that of the first initialization voltage VINT. During a black period AP8 (refer to FIG. 6B), the seventh transistor T7 may be turned on in response to the j-th black scan signal GBj provided to the j-th black scan line GBLj. During the black period AP8, the anode of the light emitting element ED may be initialized to the second initialization voltage AINT by the turned-on seventh transistor T7. In another example, the third electrode of the seventh transistor T7 may be connected to the (j+1)th write scan line and may receive the (j+1)th write scan signal as the j-th black scan signal GBj.

The eighth transistor T8 may be electrically connected between the first transistor T1 and the first drive voltage line VL1. For example, the eighth transistor T8 may include the first electrode electrically connected to the first drive voltage line VL1, the second electrode electrically connected to the first electrode of the first transistor T1, and the third electrode that receives the (1-j)th emission control signal EM1j through the (1-j)th emission control line EML1j. During a first non-emission period NEP1, the eighth transistor T8 may be turned on by the (1-j)th emission control signal EM1j provided to the (1-j)th emission control line EML1j.

The ninth transistor T9 may be electrically connected between the first transistor T1 and the bias voltage line VBL. For example, the ninth transistor T9 may include the first electrode electrically connected to the bias voltage line VBL, the second electrode electrically connected to the first electrode of the first transistor T1, and the third electrode that receives the j-th black scan signal GBj through the j-th black scan line GBLj. During the black period AP8, the ninth transistor T9 may be turned on in response to the j-th black scan signal GBj provided to the j-th black scan line GBLj. During the black period AP8, the bias voltage Vbias may be applied to the first electrode of the first transistor T1 through the turned-on ninth transistor T9.

The light emitting element ED may be electrically connected between the sixth transistor T6 and the second drive voltage line VL2. The anode of the light emitting element ED may be connected to the second electrode of the sixth transistor T6, and a cathode of the light emitting element ED may be connected to the second drive voltage line VL2. The second drive voltage ELVSS may be applied to the second drive voltage line VL2. The second drive voltage ELVSS may have a lower voltage level than the first drive voltage ELVDD. Accordingly, the light emitting element ED may emit light according to a voltage corresponding to a difference between a signal transferred through the sixth transistor T6 and the second drive voltage EVLSS.

Although only the j-th scan signals GIj, GCj, GWj, and GBj and the j-th emission control signal EMj are illustrated in FIG. 6B, the remaining scan signals and the remaining emission control signals also similarly operate, and therefore detailed descriptions thereabout will be omitted for descriptive convenience.

Referring to FIGS. 6A and 6B, the (1-j)th emission control signal EM1j may include the first non-emission period NEP1, and the (2-j)th emission control signal EM2j may include the second non-emission period NEP2. In an embodiment, the first and second non-emission periods NEP1 and NEP2 may overlap each other. A duration of the second non-emission period NEP2 may be greater than a duration of the first non-emission period NEP1. The first non-emission period NEP1 may be defined as an inactive period (e.g., a high-level period) of the (1-j)th emission control signal EM1j, and the second non-emission period NEP2 may be defined as an inactive period (e.g., a high-level period) of the (2-j)th emission control signal EM2j. A low-level period of the (2-j)th emission control signal EM2j may be defined as an emission period.

The j-th initialization scan signal GIj having the first, second, and third active periods AP1, AP2, and AP3 (e.g., low-level periods) may be generated during the second non-emission period NEP2. The j-th initialization scan signal GIj may be supplied to the fourth transistor T4 through the j-th initialization scan line GILj, and the fourth transistor T4 may be turned on during the first to third active periods AP1, AP2, and AP3 in which the j-th initialization scan signal GIj is activated. During the first to third active periods AP1, AP2, and AP3, the potential of the first node N1 may be initialized to the first initialization voltage VINT by the turned-on fourth transistor T4. For example, since the j-th initialization scan signal GIj may include the three active periods AP1, AP2, and AP3, the first node N1 may be initialized three times within the second non-emission period NEP2. Each of the first to third active periods AP1, AP2, and AP3 may be defined as an initialization period.

Among the j-th scan signals GIj, GCj, GWj, and GBj, the j-th compensation scan signal GCj may have the fourth, fifth, and sixth active periods AP4, AP5, and AP6 during the second non-emission period NEP2.

In case that the j-th compensation scan signal GCj may be supplied to the third and fifth transistors T3 and T5 through the j-th compensation scan line GCLj, the third and fifth transistors T3 and T5 may be turned on in the fourth to sixth active periods AP4, AP5, and AP6. The first transistor T1 may be diode-connected by the turned-on third transistor T3 and may be forward-biased. Then, a compensation voltage “ELVDD-Vth” obtained by subtracting the threshold voltage Vth of the first transistor T1 from the first drive voltage ELVDD may be applied to the first node N1. For example, the potential of the first node N1 may be compensated with the compensation voltage “ELVDD-Vth” in the fourth to sixth active periods AP4, AP5, and AP6. The reference voltage Vref may be applied to the second node N2 through the turned-on fifth transistor T5 during the fourth to sixth active periods AP4, AP5, and AP6.

The fourth to sixth active periods AP4, AP5, and AP6 may be defined as a compensation period. A duration of each of the fourth to sixth active periods AP4, AP5, and AP6 may be substantially equal to a duration of each of the first to third active periods AP1, AP2, and AP3.

Among the j-th scan signals GIj, GCj, GWj, and GBj, the j-th write scan signal GWj may have the seventh active period AP7 during the second non-emission period NEP2, and the j-th black scan signal GBj may have the eighth active period AP8 during the second non-emission period NEP2.

The j-th write scan signal GWj may be supplied to the second transistor T2 through the j-th write scan line GWLj, and the second transistor T2 may be turned on in the seventh active period AP7. The i-th data voltage Vdata may be applied to the second node N2 through the turned-on second transistor T2. Then, the potential of the second node N2 may be changed from the reference voltage Vref to the i-th data voltage Vdata. The potential of the first node N1 may be also changed by coupling of the first capacitor C1. The seventh active period AP7 may be referred to as a data write period.

The j-th black scan signal GBj may be supplied to the seventh transistor T7 and the ninth transistor T9 through the j-th black scan line GBLj, and the seventh transistor T7 and the ninth transistor T9 may be turned on during the eighth active period AP8. During the eighth active period AP8, the second initialization voltage AINT may be applied to the anode of the light emitting element ED through the turned-on seventh transistor T7. Then, the anode of the light emitting element ED may be initialized to the second initialization voltage AINT. Furthermore, during the eighth active period AP8, the bias voltage Vbias may be applied to the first electrode of the first transistor T1 through the turned-on ninth transistor T9.

The eighth active period AP8 may be referred to as a black period. The eighth active period AP8 may include a plurality of sub-active periods SAP8. In an embodiment, a case in which the eighth active period AP8 includes three sub-active periods SAP8 is illustrated in FIG. 6B. However, the number of sub-active periods is not limited thereto.

In an embodiment, each of the sub-active periods SAP8 may have the same duration as the seventh active period AP7. Furthermore, the duration of each of the first to sixth active periods AP1 to AP6 may be greater than or equal to a duration of each of the seventh active periods AP7 and the sub-active periods SAP8. Although FIG. 6B illustrates an example that the duration of each of the first to sixth active periods AP1 to AP6 is two times greater than the duration of the seventh active period AP7, embodiments are not limited thereto. In another example, the duration of each of the first to sixth active periods AP1 to AP6 may be three or four times greater than the duration of the seventh active period AP7.

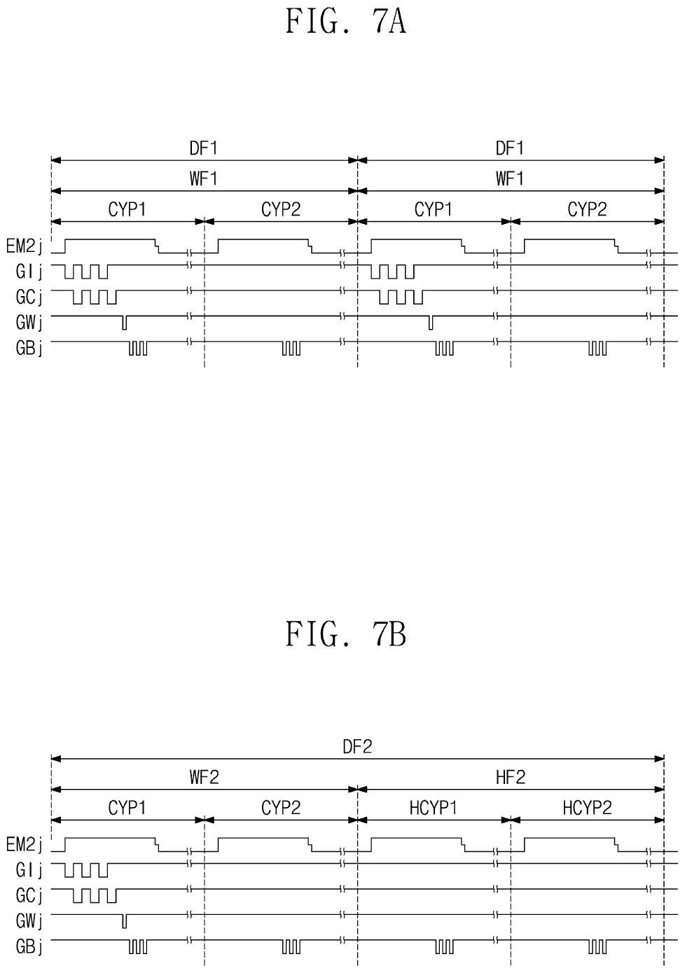

FIG. 7A is a timing chart for explaining the display device DD operating at a first drive frequency in a variable frequency mode according to an embodiment, and FIG. 7B is a timing chart for explaining the display device DD operating at a second drive frequency in the variable frequency mode according to an embodiment.

Referring to FIGS. 5, 7A, and 7B, the display device DD may operate in a normal frequency mode (e.g., a first mode) in which a drive frequency is fixed (or not varied), or may operate in a variable frequency mode (e.g., a second mode) in which a drive frequency is varied. In the variable frequency mode, the drive frequency may be varied according to a frame rate. FIG. 7A illustrates the case in which the display device DD operates at the first drive frequency in the variable frequency mode, and FIG. 7B illustrates the case in which the display device DD operates at the second drive frequency in the variable frequency mode. In an embodiment, the first drive frequency may be the highest drive frequency at which the display device DD is capable of operating. For example, the first drive frequency may be about 240 Hz or about 480 Hz. The first drive frequency may be referred to as a reference frequency or a maximum frequency. The second drive frequency may be a frequency lower than the first drive frequency. In an embodiment, the second drive frequency may be a frequency corresponding to one of compensation frequencies controlled by the drive controller 100.

As illustrated in FIGS. 5 and 7A, in case that the display device DD operates at the first drive frequency in the variable frequency mode, the scan signals GIj, GCj, GWj, and GBj and the emission control signals EM1j and EM2j may be activated within a first drive frame DF1. In an embodiment, an active period in which each of the scan signals GIj, GCj, GWj, and GBj and the emission control signals EM1j and EM2j is activated may be defined as a low level period, and an inactive period in which each of the scan signals GIj, GCj, GWj, and GBj and the emission control signals EM1j and EM2j is deactivated may be defined as a high level period. In an embodiment, the first drive frame DF1 may include a first write frame WF1. The first write frame WF1 may include a first cycle section CYP1 and a second cycle section CYP2.

Among the scan signals GIj, GCj, GWj, and GBj, the scan signals GIj, GCj, and GWj may be activated only in the first cycle section CYP1 and may remain in a deactivated state in the second cycle section CYP2. In an embodiment, the black scan signal GBj and the emission control signals EM1j and EM2j may be activated in the first and second cycle sections CYP1 and CYP2. The j-th initialization scan signal GIj, the j-th compensation scan signal GCj, and the j-th write scan signal GWj may be activated only in the first cycle section CYP1. For example, the j-th black scan signal GBj, the (1-j)th emission control signal EM1j, and the (2-j)th emission control signal EM2j may be activated in units of one cycle section, and the j-th initialization scan signal GIj, the j-th compensation scan signal GCj, and the j-th write scan signal GWj may be activated in units of one first write frame WF1. Accordingly, the frequencies of the j-th black scan signal GBj, the (1-j)th emission control signal EMlj, and the (2-j)th emission control signal EM2j may be greater than the frequencies of the j-th initialization scan signal GIj, the j-th compensation scan signal GCj, and the j-th write scan signal GWj.

As illustrated in FIGS. 5 and 7B, the display device DD may operate at the second drive frequency different from the first drive frequency in the variable frequency mode. In an embodiment, the second drive frequency may be lower than the first drive frequency. For example, the second drive frequency may be about 48 Hz or about 96 Hz. In case that the display device DD operates at the second drive frequency, the scan signals GIj, GCj, GWj, and GBj and the emission control signals EM1j and EM2j may be activated within a second drive frame DF2.

In an embodiment, the second drive frame DF2 may include a second write frame WF2 and at least one holding frame HF2. A duration of the second write frame WF2 may be substantially equal to a duration of the first write frame WF1. A duration of the holding frame HF2 may be substantially equal to the duration time of the second write frame WF2. The number of holding frames HF2 included in the second drive frame DF2 may vary according to the magnitude of the second drive frequency.

Among the scan signals GIj, GCj, GWj, and GBj, the scan signals GIj, GCj, and GWj may be activated only within the second write frame WF2 and may remain in a deactivated state in the holding frame HF2. The second write frame WF2 may include a first cycle section CYP1 and a second cycle section CYP2. The holding frame HF2 may include a first holding cycle section HCYP1 and a second holding cycle section HCYP2. In an embodiment, each of the first and second holding cycle sections HCYP1 and HCYP2 may have the same duration as the first and second cycle sections CYP1 and CYP2.

Among the scan signals GIj, GCj, GWj, and GBj, the scan signals GIj, GCj, and GWj may be activated only in the first cycle section CYP1 of the second write frame WF2 and may remain in a deactivated state in the second cycle section CYP2. The black scan signal GBj and the emission control signals EM1j and EM2j may be activated within the second write frame WF2 and the holding frame HF2. For example, the j-th black scan signal GBj, the (1-j)th emission control signal EM1j, and the (2-j)th emission control signal EM2j may be activated in units of one cycle section, and the j-th initialization scan signal GIj, the j-th compensation scan signal GCj, and the j-th write scan signal GWj may be activated in units of one second write frame WF2. Accordingly, the frequencies of the j-th black scan signal GBj, the (1-j)th emission control signal EM1j, and the (2-j)th emission control signal EM2j may be greater than the frequencies of the j-th initialization scan signal GIj, the j-th compensation scan signal GCj, and the j-th write scan signal GWj.

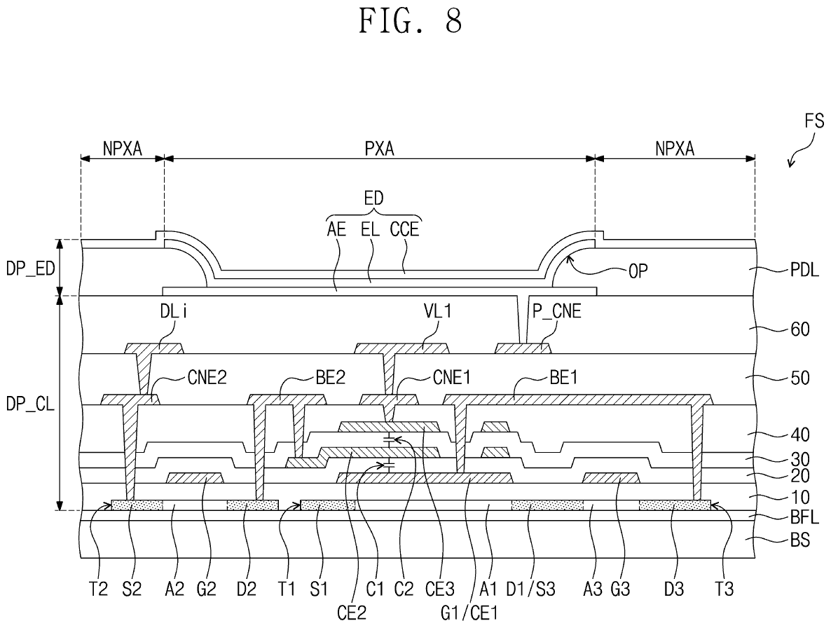

FIG. 8 is a schematic sectional view of the display panel DP according to an embodiment.

Referring to FIG. 8, the first substrate FS of the display panel DP may include the base substrate BS, the circuit layer DP_CL, and the display element layer DP_ED.

The base substrate BS may include a plastic substrate, a glass substrate, a metal substrate, or an organic/inorganic composite substrate.

At least one inorganic layer may be formed on the upper surface of the base substrate BS. The inorganic layer may include at least one of aluminum oxide, titanium oxide, silicon oxide, silicon oxy nitride, zirconium oxide, and hafnium oxide. The inorganic layer may be formed of multiple layers. The multiple inorganic layers may constitute a barrier layer and/or a buffer layer BFL. The barrier layer and the buffer layer BFL may be selectively disposed.

The barrier layer may prevent infiltration (or permeation) of foreign matter from the outside. The barrier layer may include a silicon oxide layer and a silicon nitride layer. Silicon oxide layers and silicon nitride layers may be formed (or provided). The silicon oxide layers and the silicon nitride layers may be alternately stacked each other.

The buffer layer BFL may be disposed on the base substrate BS. The buffer layer BFL may improve a coupling force between the base substrate BS and a semiconductor pattern and/or a conductive pattern. The buffer layer BFL may include silicon oxide layers and silicon nitride layers. The silicon oxide layers and the silicon nitride layers may be alternately stacked each other. In another example, at least one of the barrier layer and the buffer layer BFL may be omitted.

The circuit layer DP_CL may be disposed on the base substrate BS. The circuit layer DP_CL may include first to third semiconductor patterns disposed on the base substrate BS. The first to third semiconductor patterns may include a silicon semiconductor. The first to third semiconductor patterns may include poly silicon. However, embodiments are not limited thereto, the first to third semiconductor patterns may include amorphous silicon or an oxide semiconductor.

The first to third semiconductor patterns may have different electrical properties according to whether doping is performed or not. Each of the first to third semiconductor patterns may include a doped region and an undoped region. The doped region may be doped with an N-type dopant or a P-type dopant. A P-type transistor may include a doped region doped with a P-type dopant, and an N-type transistor may include a doped region doped with an N-type dopant.

The doped region may have a higher conductivity than the undoped region and substantially may function as an electrode or a signal line. The undoped region may substantially correspond to a channel part of a transistor. For example, a portion of each semiconductor pattern may be a channel part of a transistor, another portion may be a source or drain of the transistor, and yet another portion may be a connecting signal line (or a connecting electrode).

As illustrated in FIG. 8, the first electrode S1, the channel part A1, and the second electrode D1 of the first transistor T1 may be formed from the first semiconductor pattern. The first electrode S1 and the second electrode D1 of the first transistor T1 may extend from the channel part A1 in opposite directions. The first electrode S2, the channel part A2, and the second electrode D2 of the second transistor T2 may be formed from the second semiconductor pattern. The first electrode S2 and the second electrode D2 of the second transistor T2 may extend from the channel part A2 in opposite directions. The first electrode S3, the channel part A3, and the second electrode D3 of the third transistor T3 may be formed from the third semiconductor pattern. The first electrode S3 and the second electrode D3 of the third transistor T3 may extend from the channel part A3 in opposite directions. The first electrode S3 of the third transistor T3 and the second electrode D1 of the first transistor T1 may be integral with each other.

A first insulating layer 10 (e.g., a gate insulating layer) may be disposed on the buffer layer BFL. The first insulating layer 10 may commonly overlap the pixels PX and may cover the first to third semiconductor patterns. The first insulating layer 10 may be an inorganic layer and/or an organic layer and may have a single-layer structure or a multi-layer structure. The first insulating layer 10 may include at least one of aluminum oxide, titanium oxide, silicon oxide, silicon oxy nitride, zirconium oxide, and hafnium oxide. In an embodiment, the first insulating layer 10 may be a single silicon oxide layer. Not only the first insulating layer 10 but also insulating layers of the circuit layer DP_CL that will be described below may be inorganic layers and/or organic layers and may have a single-layer structure or a multi-layer structure. The inorganic layers may include at least one of the aforementioned materials.

The third electrode G1 of the first transistor T1, the third electrode G2 of the second transistor T2, and the third electrode G3 of the third transistor T3 may be disposed on the first insulating layer 10. The third electrode G1 of the first transistor T1 may overlap the channel part A1 of the first transistor T1, the third electrode G2 of the second transistor T2 may overlap the channel part A2 of the second transistor T2, and the third electrode G3 of the third transistor T3 may overlap the channel part A3 of the third transistor T3.

A first capacitor electrode CE1 may be additionally disposed on the first insulating layer 10. The first capacitor electrode CE1 may extend from the third electrode G1 of the first transistor T1 and may have a one-body shape with the third electrode G1 of the first transistor T1. The third electrode G1 of the first transistor T1 and the first capacitor electrode CE1 may be simultaneously formed with a first gate wiring layer GAT1 illustrated in FIGS. 9A to 9E.

A second insulating layer 20 may be disposed on the first insulating layer 10 to cover the third electrode G1 of the first transistor T1, the third electrode G2 of the second transistor T2, the third electrode G3 of the third transistor T3, and the first capacitor electrode CE1. The second insulating layer 20 may commonly overlap the pixels PX (refer to FIG. 5). The second insulating layer 20 may be an inorganic layer and/or an organic layer and may have a single-layer structure or a multi-layer structure. In an embodiment, the second insulating layer 20 may be a single silicon oxide layer.

A second capacitor electrode CE2 may be disposed on the second insulating layer 20. The second capacitor electrode CE2 may face the first capacitor electrode CE1 with the second insulating layer 20 between the first and second capacitor electrodes CE1 and CE2 to form the first capacitor C1. The second capacitor electrode CE2 may be simultaneously formed with a second gate wiring layer GAT2 illustrated in FIGS. 9A to 9E.

A third insulating layer 30 may be disposed on the second insulating layer 20 to cover the second capacitor electrode CE2. In an embodiment, the third insulating layer 30 may be a single silicon oxide layer.

A third capacitor electrode CE3 of the second capacitor C2 may be disposed on the third insulating layer 30. The third capacitor electrode CE3 may face the second capacitor electrode CE2 with the third insulating layer 30 between the second and third capacitor electrodes CE2 and CE3 to form the second capacitor C2. The third capacitor electrode CE3 may be simultaneously formed with a third gate wiring layer GAT3 illustrated in FIGS. 9A to 9E. On the section, the first capacitor C1 may be positioned between the second capacitor C2 and the first transistor T1.

A fourth insulating layer 40 may be disposed on the third insulating layer 30 to cover the third capacitor electrode CE3. In an embodiment, the fourth insulating layer 40 may be a single silicon oxide layer. A first bridge electrode BE1 and a second bridge electrode BE2 may be disposed on the fourth insulating layer 40. The first bridge electrode BE1 may be an electrode that connects the third electrode G1 of the first transistor T1 (e.g., the first capacitor electrode CE1) and the second electrode D3 of the third transistor T3. The first bridge electrode BE1 may be connected to the third electrode G1 of the first transistor T1 (e.g., the first capacitor electrode CE1) through a contact hole penetrating the second to fourth insulating layers 20, 30, and 40. Furthermore, the first bridge electrode BE1 may be connected to the second electrode D3 of the third transistor T3 through a contact hole penetrating the first to fourth insulating layers 10, 20, 30, and 40. The second bridge electrode BE2 may be an electrode that connects the second capacitor electrode CE2 and the second electrode D2 of the second transistor T2. The second bridge electrode BE2 may be connected to the second capacitor electrode CE2 through a contact hole penetrating the third and fourth insulating layers 30 and 40 and may be connected to the second electrode D2 of the second transistor T2 through a contact hole penetrating the first to fourth insulating layers 10, 20, 30, and 40. In an embodiment, the first bridge electrode BE1 may correspond to the first node N1 illustrated in FIG. 6A, and the second bridge electrode BE2 may correspond to the second node N2 illustrated in FIG. 6A.

First and second connecting electrodes CNE1 and CNE2 may be additionally disposed on the fourth insulating layer 40. The first connecting electrode CNE1 may be an electrode for connecting the third capacitor electrode CE3 to the first drive voltage line VL1. The second connecting electrode CNE2 may be an electrode for connecting the first electrode S2 of the second transistor T2 to a data line (e.g., the i-th data line DLi).

The first connecting electrode CNE1 may be connected to the third capacitor electrode CE3 through a contact hole penetrating the fourth insulating layer 40, and the second connecting electrode CNE2 may be connected to the first electrode S2 of the second transistor T2 through a contact hole penetrating the first to fourth insulating layers 10, 20, 30, and 40.

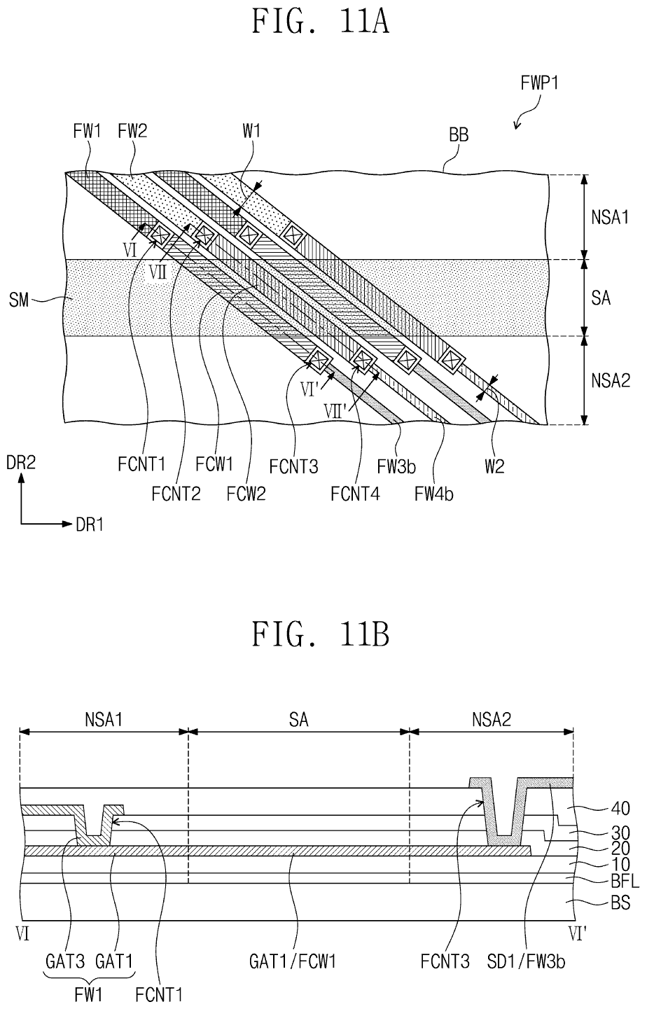

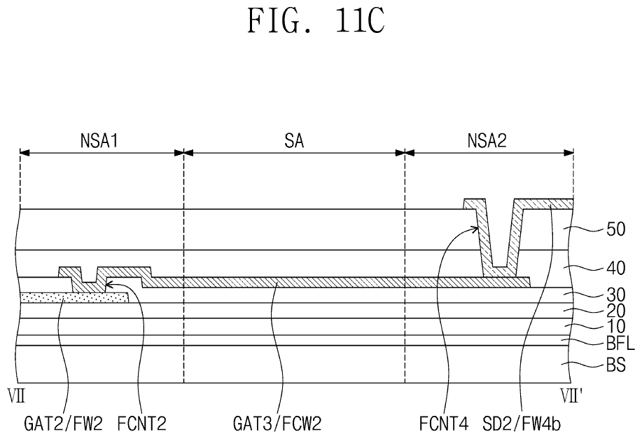

The first and second bridge electrodes BE1 and BE2 and the first and second connecting electrodes CNE1 and CNE2 may be simultaneously formed with a first data wiring layer SD1 illustrated in FIGS. 11A to 11C.

A fifth insulating layer 50 may be disposed to cover the first and second bridge electrodes BE1 and BE2 and the first and second connecting electrodes CNE1 and CNE2. The first drive voltage line VL1 and the i-th data line DLi may be disposed on the fifth insulating layer 50.

The first drive voltage line VL1 may be connected to the first connecting electrode CNE1 through a contact hole formed (or passing) through the fifth insulating layer 50, and the i-th data line DLi may be connected to the second connecting electrode CNE2 through a contact hole formed (or passing) through the fifth insulating layer 50.

An element connecting electrode P_CNE to be connected to the light emitting element ED may be additionally disposed on the fifth insulating layer 50. The element connecting electrode P_CNE may be connected to the anode AE of the light emitting element ED. The first drive voltage line VL1, the i-th data line DLi, and the element connecting electrode P_CNE may be simultaneously formed with a second data wiring layer SD2 illustrated in FIGS. 11A to 11C.

A sixth insulating layer 60 may be disposed on the fifth insulating layer 50 to cover the first drive voltage line VL1, the element connecting electrode P_CNE, and the i-th data line DLi. In an embodiment, the sixth insulating layer 60 may include a silicon oxide layer and a silicon nitride layer. The sixth insulating layer 60 may include silicon oxide layers and silicon nitride layers alternately stacked each other.

The display element layer DP_ED may be disposed on the circuit layer DP_CL. The display element layer DP_ED may include the light emitting element ED and the pixel defining layer PDL. The light emitting element ED may include the anode AE, an emissive layer EL, and the cathode CCE.

The pixel defining layer PDL may include an opening OP defined therein to correspond to the light emitting element ED. The opening OP may expose at least a portion of the anode AE of the light emitting element ED. The opening OP of the pixel defining layer PDL may define an emissive region PXA. For example, the pixels PX (refer to FIG. 5) may be arranged on the plane of the display panel DP (refer to FIG. 5) according to a certain rule. Regions where the pixels PX are disposed may be defined as pixel regions, and a pixel region may include an emissive region (e.g., light-emissive region) PXA and a non-emissive region (e.g., non-light-emissive region) NPXA adjacent to the emissive region PXA. The non-emissive region NPXA may surround the emissive region PXA.

The emissive layer EL may be disposed to correspond to the opening OP defined in the pixel defining layer PDL. Although the patterned emissive layer EL is illustrated in an embodiment, embodiments are not limited thereto. A common light emitting layer may be commonly disposed for the pixels PX. For example, the common light emitting layer may generate white light or blue light.

The cathode CCE may be disposed on the emissive layer EL. The cathode CCE may be commonly disposed for the pixels PX.

The display panel DP may further include an encapsulation layer that seals the display element layer DP_ED. The encapsulation layer may include at least one organic film and at least one inorganic film. The inorganic film may include an inorganic material and may protect the display element layer DP_ED from moisture/oxygen. The inorganic film may include a silicon nitride layer, a silicon oxy nitride layer, a silicon oxide layer, a titanium oxide layer, or an aluminum oxide layer, but embodiments are not limited thereto. The organic film may include an organic material and may protect the display element layer DP_ED from foreign matter such as dust particles.

FIG. 9A is an enlarged schematic plan view illustrating a region BB illustrated in FIG. 3 according to an embodiment. FIG. 9B is a schematic sectional view taken along line II-II′ illustrated in FIG. 9A according to an embodiment, and FIG. 9C is a schematic sectional view taken along line III-III′ illustrated in FIG. 9A according to an embodiment. FIG. 9D is a schematic sectional view taken along line II-II′ illustrated in FIG. 9A according to an embodiment, and FIG. 9E is a schematic sectional view taken along line III-III′ illustrated in FIG. 9A according to an embodiment.

Referring to FIGS. 3 and 9A, the fan-out wiring part FWP may be disposed in the peripheral region NDA of the display panel DP. FIG. 9A is an enlarged schematic view illustrating a portion of the first fan-out wiring part FWP1. For descriptive convenience, only some of the fan-out lines included in the first fan-out wiring part FWP1 are illustrated in FIG. 9A. However, since the second fan-out wiring part FWP2 also has a similar structure, description of the second fan-out wiring part FWP2 will be omitted to avoid redundancy.

The first fan-out wiring part FWP1 may include a first fan-out line FW1 and a second fan-out line FW2. The first fan-out line FW1 and the second fan-out line FW2 may have a shape extending in a direction inclined with respect to the first and second directions DR1 and DR2. The first fan-out line FW1 and the second fan-out line FW2 may be alternately disposed in the first direction DR1 (or a diagonal direction between the first and second directions DR1 and DR2).

The first fan-out line FW1 and the second fan-out line FW2 may be disposed in the non-sealing area NSA of the peripheral region NDA that does not overlap the sealant SM. For example, the first fan-out line FW1 and the second fan-out line FW2 may not be disposed in the sealing area SA where the sealant SM is disposed. In an embodiment, the non-sealing area NSA may include a first non-sealing area NSA1 positioned between the display region DA and the sealing area SA and a second non-sealing area NSA2 positioned between the sealing area SA and a driver chip (e.g., the first driver chip DIC1). The first fan-out line FW1 and the second fan-out line FW2 may be disposed in the first non-sealing area NSA1.

The first fan-out wiring part FWP1 may further include a third fan-out line FW3 and a fourth fan-out line FW4 that are disposed in the second non-sealing area NSA2. The third fan-out line FW3 and the fourth fan-out line FW4 may also have a shape extending in the direction inclined with respect to the first and second directions DR1 and DR2. The third fan-out line FW3 and the fourth fan-out line FW4 may be alternately disposed in the first direction DR1 (or a diagonal direction between the first and second directions DR1 and DR2).

The first fan-out wiring part FWP1 further may include a first connecting line FCW1 and a second connecting line FCW2. The first connecting line FCW1 and the second connecting line FCW2 may be disposed in positions overlapping the sealing area SA. Each of the first connecting line FCW1 and the second connecting line FCW2 may overlap (e.g., partially overlap) the first and second non-sealing areas NSA1 and NSA2. Each of the first connecting line FCW1 and the second connecting line FCW2 may have a shape extending in the direction inclined with respect to (or between) the first and second directions DR1 and DR2. The first connecting line FCW1 and the second connecting line FCW2 may be alternately disposed in the first direction DR1 (or a diagonal direction between the first and second directions DR1 and DR2).

The first connecting line FCW1 may be connected to the first fan-out line FW1 and the third fan-out line FW3, and the second connecting line FCW2 may be connected to the second fan-out line FW2 and the fourth fan-out line FW4. The first fan-out line FW1 and the third fan-out line FW3 may be connected to each other through the first connecting line FCW1, and the second fan-out line FW2 and the fourth fan-out line FW4 may be connected to each other through the second connecting line FCW2.

The first connecting line FCW1 may be connected to the first fan-out line FW1 through a first contact hole FCNT1 and may be connected to the third fan-out line FW3 through a third contact hole FCNT3. The second connecting line FCW2 may be connected to the second fan-out line FW2 through a second contact hole FCNT2 and may be connected to the fourth fan-out line FW4 through a fourth contact hole FCNT4. The first and second contact holes FCNT1 and FCNT2 may be positioned in the first non-sealing area NSA1, and the third and fourth contact holes FCNT3 and FCNT4 may be positioned in the second non-sealing area NSA2. For example, the first to fourth contact holes FCNT1 to FCNT4 may not be disposed in the sealing area SA and may not overlap the sealant SM in plan view (or when viewed from above the plane).

Referring to FIGS. 9A, 9B, and 9C, each of the first and third fan-out lines FW1 and FW3 may have a double-layer wiring structure. In an embodiment, each of the first and third fan-out lines FW1 and FW3 may include the first gate wiring layer GAT1 and the third gate wiring layer GAT3 disposed on the first gate wiring layer GAT1. Although the first and third gate wiring layers GAT1 and GAT3 may be disposed on different insulating layers, the third gate wiring layer GAT3 may be connected to the first gate wiring layer GAT1 through at least one contact portion. In an embodiment, the first gate wiring layer GAT1 may be disposed on the first insulating layer 10. The first gate wiring layer GAT1 and the first capacitor electrode CE1 (refer to FIG. 8) may be disposed on the same layer. The first gate wiring layer GAT1 may be covered by the second insulating layer 20.

Each of the second and fourth fan-out lines FW2 and FW4 may have a single-layer wiring structure. In an embodiment, each of the second and fourth fan-out lines FW2 and FW4 may include the second gate wiring layer GAT2. The second gate wiring layer GAT2 may be disposed on an insulating layer different from the insulating layers on which the first and third gate wiring layers GAT1 and GAT3 are disposed. In an embodiment, the second gate wiring layer GAT2 may be disposed on the second insulating layer 20. The second gate wiring layer GAT2 and the second capacitor electrode CE2 (refer to FIG. 8) may be disposed on the same layer. The second gate wiring layer GAT2 may be covered by the third insulating layer 30.

The third gate wiring layer GAT3 may be disposed on the third insulating layer 30. The third gate wiring layer GAT3 and the third capacitor electrode CE3 (refer to FIG. 8) may be disposed on the same layer.

In an embodiment, the first connecting line FCW1 may include the first gate wiring layer GAT1, and the second connecting line FCW2 may include the third gate wiring layer GAT3. For example, the first gate wiring layer GAT1 of the first connecting line FCW1 may be integral with the first gate wiring layers GAT1 of the first and third fan-out lines FW1 and FW3. The first gate wiring layer GAT1 of the first connecting line FCW1 may be connected to the third gate wiring layers GAT3 of the first and third fan-out lines FW1 and FW3 through the first and third contact holes FCNT1 and FCNT3. The third gate wiring layer GAT3 of the second connecting line FCW2 may be connected to the second gate wiring layers GAT2 of the second and fourth fan-out lines FW2 and FW4 through the second and fourth contact holes FCNT2 and FCNT4 formed (or passing) through the third insulating layer 30.

Each of the first and third gate wiring layers GAT1 and GAT3 may have a single-layer structure, and the second gate wiring layer GAT2 may have a multi-layer structure in which metal layers are sequentially stacked each other. In an embodiment, each of the first and third gate wiring layers GAT1 and GAT3 may include silver (Ag), an alloy containing silver, molybdenum (Mo), an alloy containing molybdenum, tungsten (W), tungsten nitride (WN), copper (Cu), or the like. The second gate wiring layer GAT2 may have a double-layer structure including a first metal layer and a second metal layer stacked (e.g., directly stacked) on the first metal layer. For example, the first metal layer may include titanium (Ti), an alloy containing titanium, or titanium nitride (TiN), and the second metal layer may include aluminum (Al), an alloy containing aluminum, or aluminum nitride. In another example, the second gate wiring layer GAT2 may have a triple-layer structure that includes a first metal layer, a second metal layer stacked (e.g., directly stacked) on the first metal layer, and a third metal layer stacked (e.g., directly stacked) on the second metal layer. For example, the first metal layer may include titanium (Ti) and an alloy containing titanium, the second metal layer may include titanium nitride (TiN), and the third metal layer may include aluminum (Al), an alloy containing aluminum, or aluminum nitride.

The second gate wiring layer GAT2 may have a lower sheet resistance than the first and third gate wiring layers GAT1 and GAT3. The first and third gate wiring layers GAT1 and GAT3 may have the same sheet resistance. In an embodiment, the second gate wiring layer GAT2 may have a sheet resistance corresponding to half of the sheet resistance of each of the first and third gate wiring layers GAT1 and GAT3.

Since each of the first and third fan-out lines FW1 and FW3 has a double-layer wiring structure formed of the first and third gate wiring layers GAT1 and GAT3, the sheet resistance of each of the first and third fan-out lines FW1 and FW3 may be lowered even though the sheet resistance of each of the first and third gate wiring layers GAT1 and GAT3 may be higher than that of the second gate wiring layer GAT2. For example, each of the first and third fan-out lines FW1 and FW3 may have a sheet resistance similar to (or substantially the same as) that of each of the second and fourth fan-out lines FW2 and FW4. Accordingly, a difference in wiring resistance between the fan-out lines may be decreased.

Since each of the first and third fan-out lines FW1 and FW3 is formed in a double-layer wiring structure and the second and fourth fan-out lines FW2 and FW4 are formed of the second gate wiring layer GAT2 having a low sheet resistance, the overall wiring resistance of the first to fourth fan-out lines FW1 to FW4 may be decreased.

For example, since the second gate wiring layer GAT2, which includes aluminum (Al), an alloy containing aluminum, or aluminum nitride, is not disposed in the sealing area SA, the second gate wiring layer GAT2 may not overlap the sealant SM in plan view (or when viewed from above the plane). In a laser irradiation process for melting the sealant SM, defects such as a short circuit between the fan-out lines due to aluminum eluted by heat generated by a laser may be prevented.

In FIGS. 9A to 9C, the structure in which the first connecting line FCW1 includes the first gate wiring layer GAT1 and the second connecting line FCW2 includes the third gate wiring layer GAT3 is illustrated. However, embodiments are not limited thereto. As illustrated in FIGS. 9D and 9E, a first connecting line FCW1a may include the third gate wiring layer GAT3, and a second connecting line FCW2a may include the first gate wiring layer GAT1. For example, the third gate wiring layer GAT3 of the first connecting line FCW1a may be integral with the third gate wiring layers GAT3 of the first and third fan-out lines FW1 and FW3.

The third gate wiring layer GAT3 of the first connecting line FCW1a may be connected to the first gate wiring layers GAT1 of the first and third fan-out lines FW1 and FW3 through the first and third contact holes FCNT1 and FCNT3 formed (or passing) through the second and third insulating layers 20 and 30. The first gate wiring layer GAT1 of the second connecting line FCW2a may be connected to the second gate wiring layers GAT2 of the second and fourth fan-out lines FW2 and FW4 through the second and fourth contact holes FCNT2 and FCNT4 formed (or passing) through the second insulating layer 20.

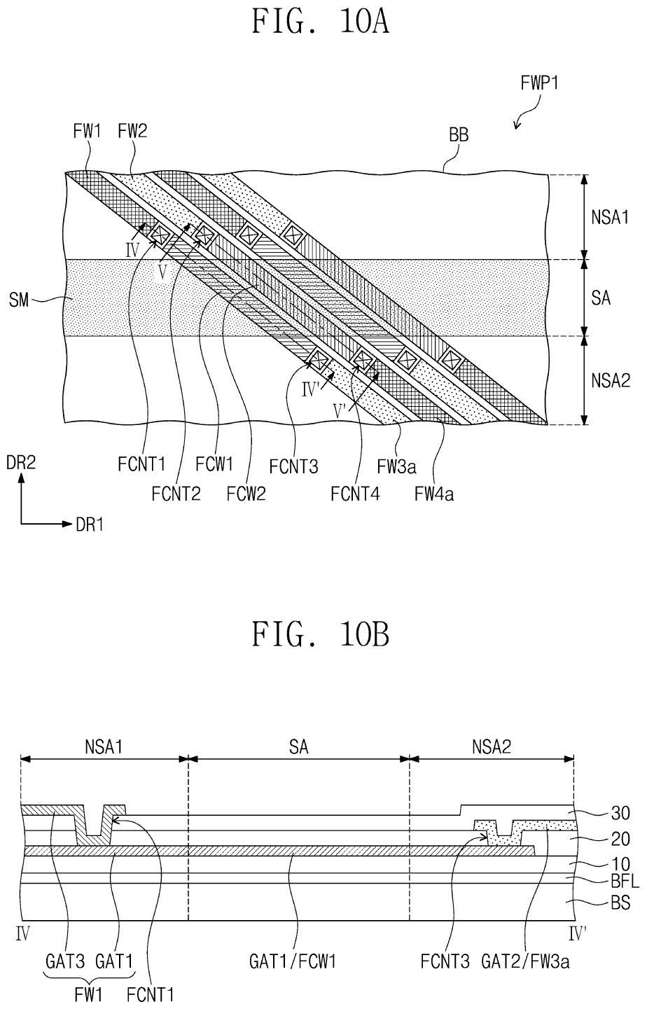

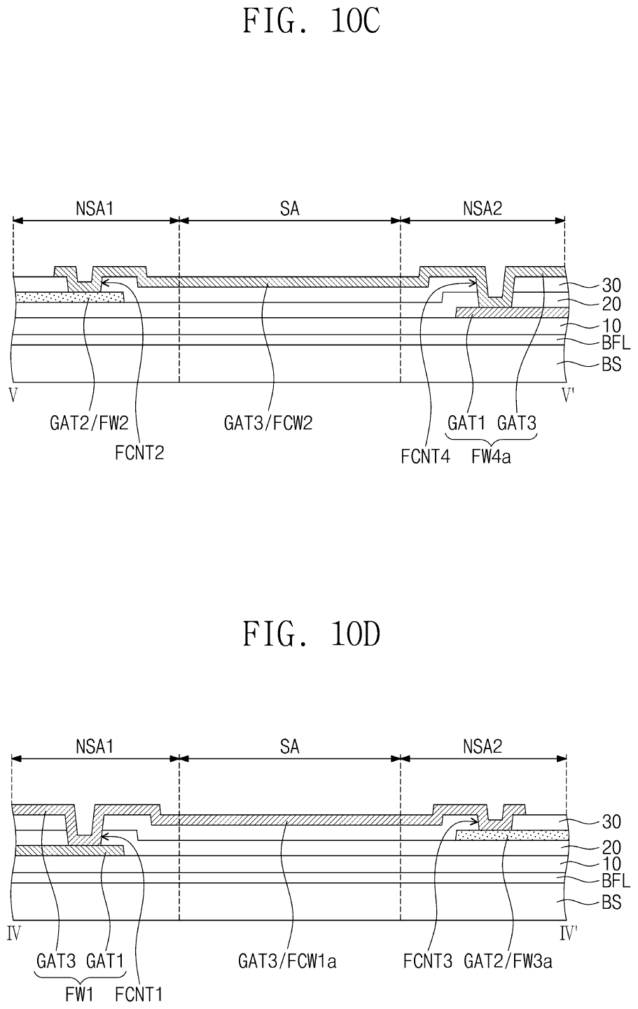

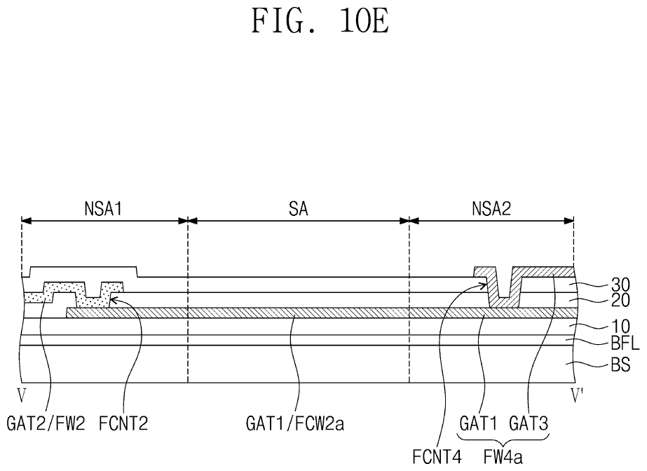

FIG. 10A is an enlarged schematic plan view illustrating the region BB illustrated in FIG. 3 according to an embodiment. FIG. 10B is a schematic sectional view taken along line IV-IV′ illustrated in FIG. 10A according to an embodiment, and FIG. 10C is a schematic sectional view taken along line V-V′ illustrated in FIG. 10A according to an embodiment. FIG. 10D is a schematic sectional view taken along line IV-IV′ illustrated in FIG. 10A according to an embodiment, and FIG. 10E is a schematic sectional view taken along line V-V′ illustrated in FIG. 10A according to an embodiment.

Referring to FIG. 10A, the first fan-out wiring part FWP1 may include a first fan-out line FW1, a second fan-out line FW2, a first connecting line FCW1, a second connecting line FCW2, a third fan-out line FW3a, and a fourth fan-out line FW4a.

In FIG. 9A, the third fan-out line FW3 may have the same wiring structure as the first fan-out line FW1, and the fourth fan-out line FW4 may have the same wiring structure as the second fan-out line FW2. However, in FIG. 10A, the third fan-out line FW3a may have the same wiring structure as the second fan-out line FW2, and the fourth fan-out line FW4a may have the same wiring structure as the first fan-out line FW1.

Referring to FIGS. 10A, 10B, and 10C, each of the first and fourth fan-out lines FW1 and FW4a may have a double-layer wiring structure. In an embodiment, each of the first and fourth fan-out lines FW1 and FW4a may include the first gate wiring layer GAT1 and the third gate wiring layer GAT3 disposed on the first gate wiring layer GAT1. Each of the second and third fan-out lines FW2 and FW3a may have a single-layer wiring structure. In an embodiment, each of the second and third fan-out lines FW2 and FW3a may include the second gate wiring layer GAT2.

The first connecting line FCW1 may include the first gate wiring layer GAT1, and the second connecting line FCW2 may include the third gate wiring layer GAT3. For example, the first gate wiring layer GAT1 of the first connecting line FCW1 may be integral with the first gate wiring layer GAT1 of the first fan-out line FW1. The third gate wiring layer GAT3 of the second connecting line FCW2 may be integral with the third gate wiring layer GAT3 of the fourth fan-out line FW4a.

The first gate wiring layer GAT1 of the first connecting line FCW1 may be connected to the third gate wiring layer GAT3 of the first fan-out line FW1 through a first contact hole FCNT1 formed (or passing) through the second and third insulating layers 20 and 30. The first gate wiring layer GAT1 of the first connecting line FCW1 may be connected to the second gate wiring layer GAT2 of the third fan-out line FW3a through a third contact hole FCNT3 formed (or passing) through the second insulating layer 20.

The third gate wiring layer GAT3 of the second connecting line FCW2 may be connected to the second gate wiring layer GAT2 of the second fan-out line FW2 through a second contact hole FCNT2 formed (or passing) through the third insulating layer 30. The third gate wiring layer GAT3 of the second connecting line FCW2 may be connected to the first gate wiring layer GAT1 of the fourth fan-out line FW4a through a fourth contact hole FCNT4 formed (or passing) through the second and third insulating layers 20 and 30.

In FIGS. 10A to 10C, the structure in which the first connecting line FCW1 includes the first gate wiring layer GAT1 and the second connecting line FCW2 includes the third gate wiring layer GAT3 is illustrated. However, embodiments are not limited thereto. As illustrated in FIGS. 10D and 10E, a first connecting line FCW1a may include the third gate wiring layer GAT3, and a second connecting line FCW2a may include the first gate wiring layer GAT1. For example, the third gate wiring layer GAT3 of the first connecting line FCW1a may be integral with the third gate wiring layer GAT3 of the first fan-out line FW1, and the first gate wiring layer GAT1 of the second connecting line FCW2a may be integral with the first gate wiring layer GAT1 of the fourth fan-out line FW4a.

The third gate wiring layer GAT3 of the first connecting line FCW1a may be connected to the first gate wiring layer GAT1 of the first fan-out line FW1 through the first contact hole FCNT1 formed (or passing) through the second and third insulating layers 20 and 30. The third gate wiring layer GAT3 of the first connecting line FCW1a may be connected to the second gate wiring layer GAT2 of the third fan-out line FW3a through the third contact hole FCNT3 formed (or passing) through the third insulating layer 30.

The first gate wiring layer GAT1 of the second connecting line FCW2a may be connected to the second gate wiring layer GAT2 of the second fan-out line FW2 through the second contact hole FCNT2 formed (or passing) through the second insulating layer 20. The first gate wiring layer GAT1 of the second connecting line FCW2a may be connected to the third gate wiring layer GAT3 of the fourth fan-out line FW4a through the fourth contact hole FCNT4 formed (or passing) through the second and third insulating layers 20 and 30.

In FIGS. 9A to 10E, the case in which the second gate wiring layer GAT2 is a low-resistance wiring layer having a lower sheet resistance than the first and third gate wiring layers GAT1 and GAT3 has been described as an example. However, embodiments are not limited thereto. For example, one of the first and third gate wiring layers GAT1 and GAT3 may be formed to be a low-resistance wiring layer. For example, the first fan-out line FW1 may have a double-layer wiring structure including the second and third gate wiring layers GAT2 and GAT3 or a double-layer wiring structure including the first and second gate wiring layers GAT1 and GAT2. For example, the second fan-out line FW2 may have a single-layer wiring structure including the first gate wiring layer GAT1 or a single-layer wiring structure including the third gate wiring layer GAT3.

FIG. 11A is an enlarged schematic plan view illustrating the region BB illustrated in FIG. 3 according to an embodiment. FIG. 11B is a schematic sectional view taken along line VI-VI′ illustrated in FIG. 11A according to an embodiment, and FIG. 11C is a schematic sectional view taken along line VII-VII′ illustrated in FIG. 11A according to an embodiment.

Referring to FIG. 11A, the first fan-out wiring part FWP1 may include a first fan-out line FW1, a second fan-out line FW2, a first connecting line FCW1, a second connecting line FCW2, a third fan-out line FW3b, and a fourth fan-out line FW4b.

In FIG. 9A, the third fan-out line FW3 may have the same wiring structure as the first fan-out line FW1, and the fourth fan-out line FW4 may have the same wiring structure as the second fan-out line FW2. However, in FIG. 11A, the third fan-out line FW3b may have a wiring structure different from that of the first fan-out line FW1, and the fourth fan-out line FW4b may have a wiring structure different from that of the second fan-out line FW2.

Referring to FIGS. 11A, 11B, and 11C, the first fan-out line FW1 may have a double-layer wiring structure, and each of the second to fourth fan-out lines FW2, FW3b, and FW4b may have a single-layer wiring structure. In an embodiment, the first fan-out line FW1 may include the first gate wiring layer GAT1 and the third gate wiring layer GAT3 disposed on the first gate wiring layer GAT1. The second fan-out line FW2 may include the second gate wiring layer GAT2. In an embodiment, the third fan-out line FW3b may include the first data wiring layer SD1, and the fourth fan-out line FW4b may include the second data wiring layer SD2. The first data wiring layer SD1 may be disposed on the fourth insulating layer 40. The first data wiring layer SD1 and the first and second connecting electrodes CNE1 and CNE2 (illustrated in FIG. 8) may be disposed on the same layer. The second data wiring layer SD2 may be disposed on the fifth insulating layer 50. The second data wiring layer SD2, the element connecting electrode P_CNE (refer to FIG. 8), and the first drive voltage line VL1 (refer to FIG. 8) may be disposed on the same layer. The third fan-out line FW3b and the fourth fan-out line FW4b may be alternately disposed in the first direction DR1 (or a diagonal direction between the first and second directions DR1 and DR2).

The first connecting line FCW1 may include the first gate wiring layer GAT1, and the second connecting line FCW2 may include the third gate wiring layer GAT3. For example, the first gate wiring layer GAT1 of the first connecting line FCW1 may be integral with the first gate wiring layer GAT1 of the first fan-out line FW1.

The first gate wiring layer GAT1 of the first connecting line FCW1 may be connected to the third gate wiring layer GAT3 of the first fan-out line FW1 through a first contact hole FCNT1 formed (or passing) through the second and third insulating layers 20 and 30. The first gate wiring layer GAT1 of the first connecting line FCW1 may be connected to the first data wiring layer SD1 of the third fan-out line FW3b through a third contact hole FCNT3 formed (or passing) through the second to fourth insulating layers 20, 30, and 40.

The third gate wiring layer GAT3 of the second connecting line FCW2 may be connected to the second gate wiring layer GAT2 of the second fan-out line FW2 through a second contact hole FCNT2 formed (or passing) through the third insulating layer 30. The third gate wiring layer GAT3 of the second connecting line FCW2 may be connected to the second data wiring layer SD2 of the fourth fan-out line FW4b through a fourth contact hole FCNT4 formed (or passing) through the fourth and fifth insulating layers 40 and 50.

Each of the first and second data wiring layers SD1 and SD2 may include metal, an alloy, conductive metal oxide, or a transparent conductive material. In an embodiment, the first and second data wiring layers SD1 and SD2 may include the same material. In another example, the first and second data wiring layers SD1 and SD2 may include different materials. Each of the first and second data wiring layers SD1 and SD2 may have a lower sheet resistance than the first to third gate wiring layers GAT1, GAT2, and GAT3. Accordingly, each of the third and fourth fan-out lines FW3b and FW4b may have a smaller width than the first and second fan-out lines FW1 and FW2.

Referring to FIG. 11A, the first and second fan-out lines FW1 and FW2 may have the same width (e.g., a first width W1). The third and fourth fan-out lines FW3b and FW4b may have the same width (e.g., a second width W2). In an embodiment, the second width W2 may be smaller than or equal to the first width W1.

Since the first and second data wiring layers SD1 and SD2 having a lower sheet resistance than the first to third gate wiring layers GAT1, GAT2, and GAT3 are used for the third and fourth fan-out lines FW3b and FW4b, the overall wiring resistance of the first fan-out wiring part FWP1 may be decreased.

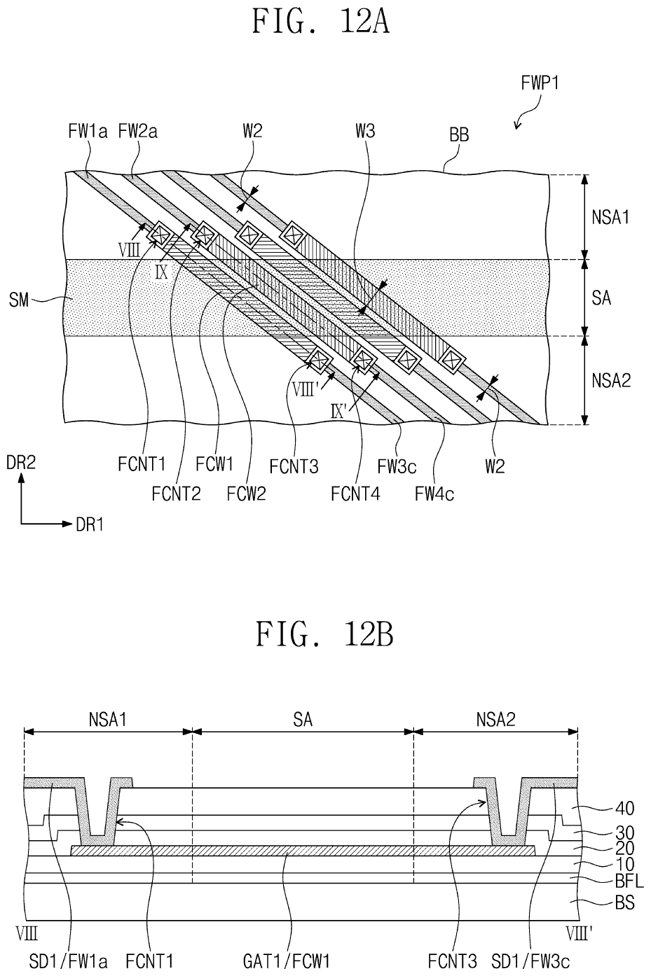

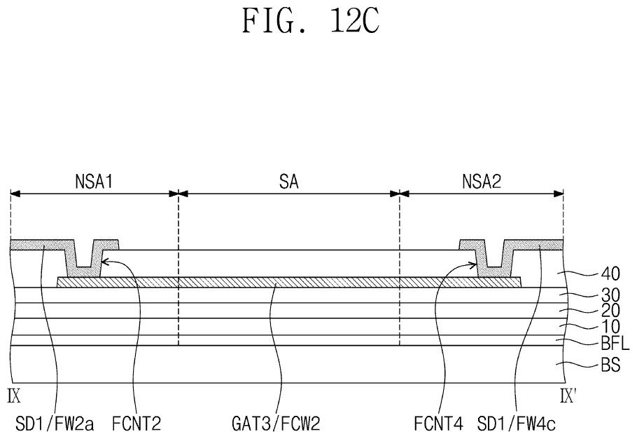

FIG. 12A is an enlarged schematic plan view illustrating the region BB illustrated in FIG. 3 according to an embodiment. FIG. 12B is a schematic sectional view taken along line VIII-VIII′ illustrated in FIG. 12A according to an embodiment, and FIG. 12C is a schematic sectional view taken along line IX-IX′ illustrated in FIG. 12A according to an embodiment.

Referring to FIG. 12A, the first fan-out wiring part FWP1 may include a first fan-out line FW1a, a second fan-out line FW2a, a first connecting line FCW1, a second connecting line FCW2, a third fan-out line FW3c, and a fourth fan-out line FW4c. The first to fourth fan-out lines FW1a, FW2a, FW3c, and FW4c may have the same wiring structure.

Referring to FIGS. 12A, 12B, and 12C, each of the first to fourth fan-out lines FW1a, FW2a, FW3c, and FW4c may have a single-layer wiring structure. In an embodiment, each of the first to fourth fan-out lines FW1a, FW2a, FW3c, and FW4c may include the first data wiring layer SD1. However, embodiments are not limited thereto. For example, each of the first to fourth fan-out lines FW1a, FW2a, FW3c, and FW4c may include the second data wiring layer SD2 (refer to FIG. 11C). In another example, the first and second fan-out lines FW1a and FW2a may include the first data wiring layer SD1, and the third and fourth fan-out lines FW3c and FW4c may include the second data wiring layer SD2.

The first connecting line FCW1 may include the first gate wiring layer GAT1, and the second connecting line FCW2 may include the third gate wiring layer GAT3. The first gate wiring layer GAT1 of the first connecting line FCW1 may be connected to the first data wiring layers SD1 of the first and third fan-out lines FW1a and FW3c through first and third contact holes FCNT1 and FCNT3 formed (or passing) through the second, third, and fourth insulating layers 20, 30, and 40. The third gate wiring layer GAT3 of the second connecting line FCW2 may be connected to the first data wiring layers SD1 of the second and fourth fan-out lines FW2a and FW4c through the second and fourth contact holes FCNT2 and FCNT4 formed (or passing) through the fourth insulating layer 40.

The first data wiring layer SD1 may have a lower sheet resistance than the first to third gate wiring layers GAT1, GAT2, and GAT3. Accordingly, each of the first to fourth fan-out lines FW1a, FW2a, FW3c, and FW4c may have a smaller width than the first and second connecting lines FCW1 and FCW2.

Referring to FIG. 12A, the first to fourth fan-out lines FW1a, FW2a, FW3c, and FW4c may have the same width (e.g., a second width W2). The first and second connecting lines FCW1 and FCW2 may have the same width (e.g., a third width W3). In an embodiment, the second width W2 may be smaller than or equal to the third width W3.

Since the first or second data wiring layer SD1 or SD2 having a lower sheet resistance than the first to third gate wiring layers GAT1, GAT2, and GAT3 is used for the first to fourth fan-out lines FW1a, FW2a, FW3c, and FW4c, the overall wiring resistance of the first fan-out wiring part FWP1 may be decreased.

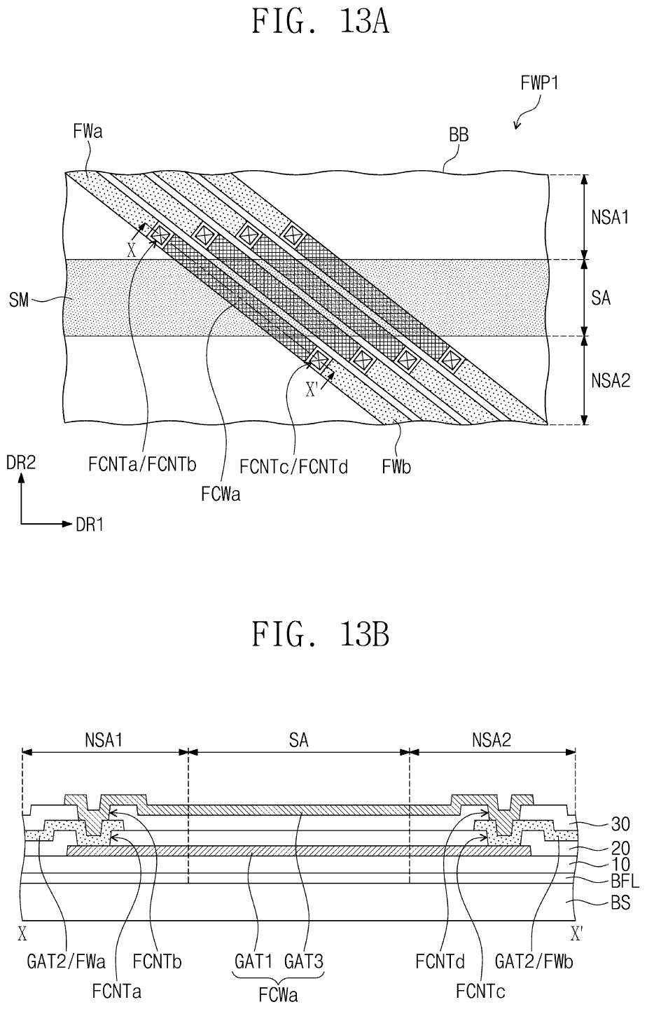

FIG. 13A is an enlarged schematic plan view illustrating the region BB illustrated in FIG. 3 according to an embodiment. FIG. 13B is a schematic sectional view taken along line X-X′ illustrated in FIG. 13A according to an embodiment.

Referring to FIGS. 13A and 13B, the first fan-out wiring part FWP1 may include first-side fan-out lines FWa and second-side fan-out lines FWb. The first-side fan-out lines FWa may be disposed in a first non-sealing area NSA1 and arranged in the first direction DR1. The second-side fan-out lines FWb may be disposed in a second non-sealing area NSA2 and arranged in the first direction DR1. The first-side fan-out lines FWa and the second-side fan-out lines FWb may not be disposed in the sealing area SA and may not overlap the sealant SM in plan view (or when viewed from above the plane). Each of the first-side fan-out lines FWa and the second-side fan-out lines FWb may have a single-layer wiring structure. In an embodiment, each of the first-side fan-out lines FWa and the second-side fan-out lines FWb may include the second gate wiring layer GAT2.

The first fan-out wiring part FWP1 may further include connecting lines FCWa. The connecting lines FCWa may connect the first-side fan-out lines FWa and the second-side fan-out lines FWb. The connecting lines FCWa may be disposed in the sealing area SA and may overlap the sealant SM in plan view (or when viewed from above the plane). The connecting lines FCWa may overlap (e.g., partially overlap) the first and second non-sealing areas NSA1 and NSA2. Each of the connecting lines FCWa may have a double-layer wiring structure. In an embodiment, each of the connecting lines FCWa may include the first gate wiring layer GAT1 and the third gate wiring layer GAT3 disposed on the first gate wiring layer GAT1.

The first gate wiring layer GAT1 of each of the connecting lines FCWa may be connected to the second gate wiring layers GAT2 of the first-side and second-side fan-out lines FWa and FWb through first and third contact holes FCNTa and FCNTc formed (or passing) through the second insulating layer 20. The third gate wiring layer GAT3 of each of the connecting lines FCWa may be connected to the second gate wiring layers GAT2 of the first-side and second-side fan-out lines FWa and FWb through second and fourth contact holes FCNTb and FCNTd formed (or passing) through the third insulating layer 30.

The second gate wiring layer GAT2 may have a lower sheet resistance than the first and third gate wiring layers GAT1 and GAT3. Accordingly, by forming each of the first-side and second-side fan-out lines FWa and FWb with the second gate wiring layer GAT2, the overall wiring resistance of the first-side and second-side fan-out lines FWa and FWb may be decreased.

Since the first-side fan-out lines FWa are formed of the same material and the second-side fan-out lines FWb are formed of the same material, a deviation in wiring resistance between the fan-out lines may be decreased.

Although each of the first and second connecting lines FCW1 and FCW2 or FCW1a and FCW2a may have a single-layer wiring structure in FIGS. 9A to 12C, each of the connecting lines FCWa in FIGS. 13A and 13B may have a double-layer wiring structure. In case that each of the connecting lines FCWa may have a double-layer wiring structure, the connecting line FCWa may have a lower sheet resistance than the first and second connecting lines FCW1 and FCW2 or FCW1a and FCW2a having a single-layer wiring structure. Accordingly, the overall wiring resistance of the first fan-out wiring part FWP1 may be further decreased.

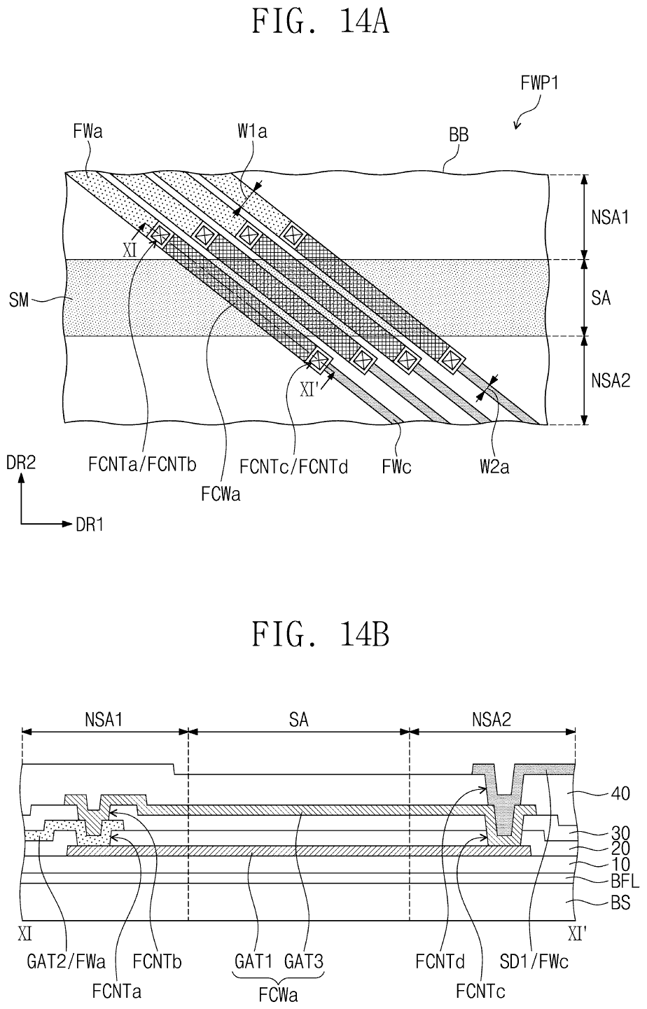

FIG. 14A is an enlarged schematic plan view illustrating the region BB illustrated in FIG. 3 according to an embodiment. FIG. 14B is a schematic sectional view taken along line XI-XI′ illustrated in FIG. 14A according to an embodiment.

Referring to FIGS. 14A and 14B, the first fan-out wiring part FWP1 may include first-side fan-out lines FWa and second-side fan-out lines FWc. Each of the first-side fan-out lines FWa and the second-side fan-out lines FWc may have a single-layer wiring structure. In an embodiment, each of the first-side fan-out lines FWa may include the second gate wiring layer GAT2, and each of the second-side fan-out lines FWc may include the first data wiring layer SD1. In another example, each of the second-side fan-out lines FWc may include the second data wiring layer SD2 (refer to FIG. 11C).

The first fan-out wiring part FWP1 may further include connecting lines FCWa. The connecting lines FCWa may connect the first-side fan-out lines FWa and the second-side fan-out lines FWc. Each of the connecting lines FCWa may have a double-layer wiring structure. In an embodiment, each of the connecting lines FCWa may include the first gate wiring layer GAT1 and the third gate wiring layer GAT3 disposed on the first gate wiring layer GAT1.

The first gate wiring layers GAT1 of the connecting lines FCWa may be connected to the second gate wiring layers GAT2 of the first-side fan-out lines FWa through first contact holes FCNTa formed (or passing) through the second insulating layer 20. The first gate wiring layers GAT1 of the connecting lines FCWa may be connected to the third gate wiring layers GAT3 of the connecting lines FCWa through third contact holes FCNTc formed (or passing) through the second and third insulating layers 20 and 30. The third gate wiring layers GAT3 of the connecting lines FCWa may be connected to the second gate wiring layers GAT2 of the first-side fan-out lines FWa through second contact holes FCNTb formed (or passing) through the third insulating layer 30. The third gate wiring layers GAT3 of the connecting lines FCWa may be connected to the first data wiring layers SD1 of the second-side fan-out lines FWc through fourth contact holes FCNTd formed (or passing) through the fourth insulating layer 40.

The second gate wiring layer GAT2 may have a lower sheet resistance than the first and third gate wiring layers GAT1 and GAT3, and the first data wiring layer SD1 may have a lower sheet resistance than the first gate wiring layer GAT1. In an embodiment, the second-side fan-out lines FWc may have a width (e.g., a second width W2a) smaller than or equal to the widths (e.g., a first widths W1a) of the first-side fan-out lines FWa. Since each of the first-side and second-side fan-out lines FWa and FWc is formed of the second gate wiring layer GAT2 or the first data wiring layer SD1 that has a low sheet resistance, the wiring resistances of the first-side and second-side fan-out lines FWa and FWc may be further decreased.

Although each of the first and second connecting lines FCW1 and FCW2 or FCW1a and FCW2a has a single-layer wiring structure in FIGS. 9A to 12C, each of the connecting lines FCWa in FIGS. 14A and 14B may have a double-layer wiring structure. In case that each of the connecting lines FCWa has a double-layer wiring structure, the connecting line FCWa may have a lower sheet resistance than the first and second connecting lines FCW1 and FCW2 or FCW1a and FCW2a having a single-layer wiring structure. Accordingly, the overall wiring resistance of the first fan-out wiring part FWP1 may be further decreased.

In FIGS. 13B and 14B, the structure in which the first and second contact holes FCNTa and FCNTb overlap each other in plan view (or when viewed from above the plane) and the third and fourth contact holes FCNTc and FCNTd overlap each other in plan view (or when viewed from above the plane) is illustrated. However, embodiments are not limited thereto. For example, the first and second contact holes FCNTa and FCNTb may not overlap each other in plan view (or when viewed from above the plane), and the third and fourth contact holes FCNTc and FCNTd may not overlap each other in plan view (or when viewed from above the plane).

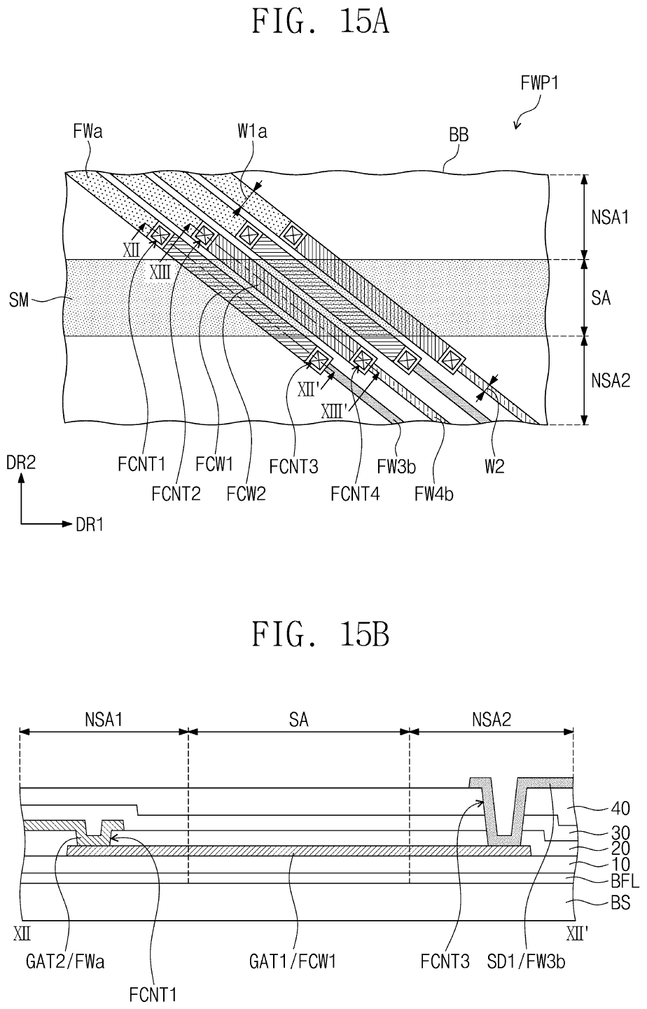

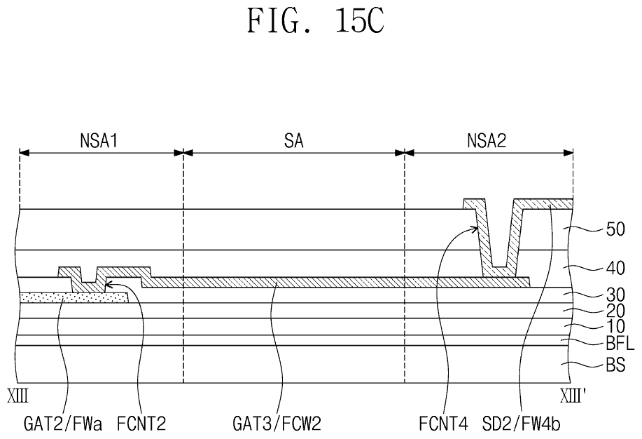

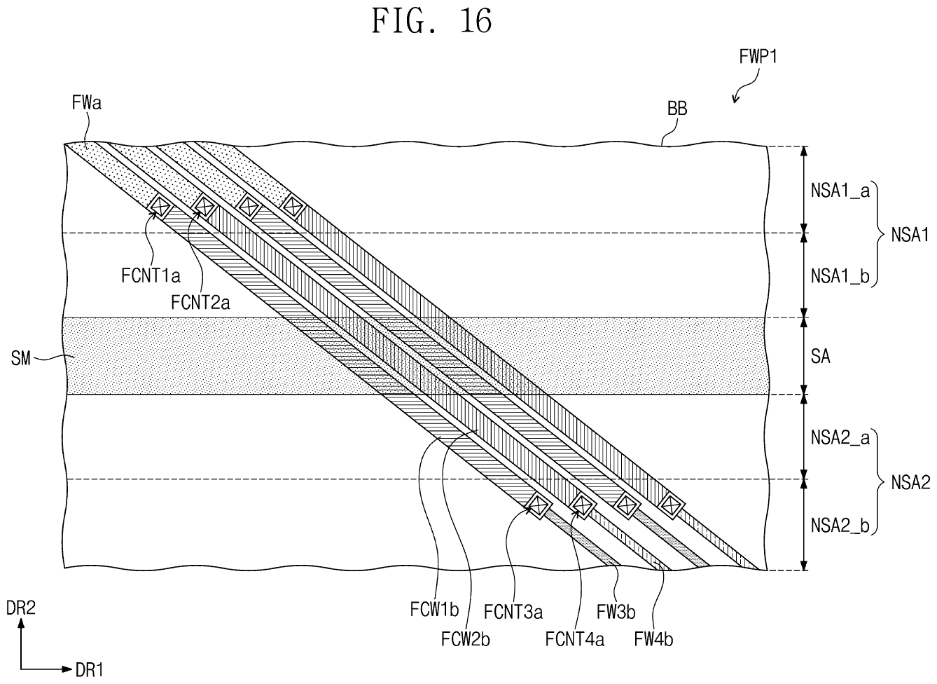

FIG. 15A is an enlarged schematic plan view illustrating the region BB illustrated in FIG. 3 according to an embodiment. FIG. 15B is a schematic sectional view taken along line XII-XII′ illustrated in FIG. 15A according to an embodiment, and FIG. 15C is a schematic sectional view taken along line XIII-XIII′ illustrated in FIG. 15A according to an embodiment.

Referring to FIGS. 15A to 15C, the first fan-out wiring part FWP1 may include first-side fan-out lines FWa and third and fourth fan-out lines FW3b and FW4b. The first-side fan-out lines FWa may have a single-layer wiring structure. In an embodiment, each of the first-side fan-out lines FWa may include the second gate wiring layer GAT2. Each of the third and fourth fan-out lines FW3b and FW4b may have a single-layer wiring structure. In an embodiment, the third fan-out line FW3b may include the first data wiring layer SD1, and the fourth fan-out line FW4b may include the second data wiring layer SD2. The first data wiring layer SD1 may be disposed on the fourth insulating layer 40. The first data wiring layer SD1 and the first and second connecting electrodes CNE1 and CNE2 (illustrated in FIG. 8) may be disposed on the same layer. The second data wiring layer SD2 may be disposed on the fifth insulating layer 50. The second data wiring layer SD2, the element connecting electrode P_CNE (refer to FIG. 8), and the first drive voltage line VL1 (refer to FIG. 8) may be disposed on the same layer. The third fan-out line FW3b and the fourth fan-out line FW4b may be alternately disposed in the first direction DR1 (or a diagonal direction between the first and second directions DR1 and DR2).

A first connecting line FCW1 may connect a part of the first-side fan-out lines FWa to the third fan-out line FW3b, and a second connecting line FCW2 may connect a part of the first-side fan-out lines FWa to the fourth fan-out line FW4b. The first connecting line FCW1 may include the first gate wiring layer GAT1, and the second connecting line FCW2 may include the third gate wiring layer GAT3.

The first gate wiring layer GAT1 of the first connecting line FCW1 may be connected to the second gate wiring layer GAT2 of the first-side fan-out line FWa through a first contact hole FCNT1 formed (or passing) through the second insulating layer 20. The first gate wiring layer GAT1 of the first connecting line FCW1 may be connected to the first data wiring layer SD1 of the third fan-out line FW3b through a third contact hole FCNT3 formed (or passing) through the second to fourth insulating layers 20, 30, and 40.

The third gate wiring layer GAT3 of the second connecting line FCW2 may be connected to the second gate wiring layer GAT2 of the first-side fan-out line FWa through a second contact hole FCNT2 formed (or passing) through the third insulating layer 30. The third gate wiring layer GAT3 of the second connecting line FCW2 may be connected to the second data wiring layer SD2 of the fourth fan-out line FW4b through a fourth contact hole FCNT4 formed (or passing) through the fourth and fifth insulating layers 40 and 50.

Each of the first and second data wiring layers SD1 and SD2 may include metal, an alloy, conductive metal oxide, or a transparent conductive material. In an embodiment, the first and second data wiring layers SD1 and SD2 may include the same material. In another example, the first and second data wiring layers SD1 and SD2 may include different materials. Each of the first and second data wiring layers SD1 and SD2 may have a lower sheet resistance than the first to third gate wiring layers GAT1, GAT2, and GAT3. Accordingly, each of the third and fourth fan-out lines FW3b and FW4b may have a smaller width than the first-side fan-out line FWa.

Since the first and second data wiring layers SD1 and SD2 having a lower sheet resistance than the first to third gate wiring layers GAT1, GAT2, and GAT3 are used for the third and fourth fan-out lines FW3b and FW4b, the overall wiring resistance of the first fan-out wiring part FWP1 may be decreased.

FIG. 16 is an enlarged schematic plan view illustrating the region BB illustrated in FIG. 3 according to an embodiment.

Referring to FIGS. 3 and 16, the peripheral region NDA of the display panel DP may include the sealing area SA and first and second non-sealing areas NSA1 and NSA2. The first non-sealing area NSA1 may include a first wiring area NSA1_a and a second wiring area NSA1_b, and the second non-sealing area NSA2 may include a third wiring area NSA2_a and a fourth wiring area NSA2_b. First-side fan-out lines FWa may be disposed in the first wiring area NSA1_a, and third and fourth fan-out lines FW3b and FW4b may be disposed in the fourth wiring area NSA2_b.

A first connecting line FCW1b may connect a part of the first-side fan-out lines FWa to the third fan-out line FW3b, and a second connecting line FCW2b may connect a part of the first-side fan-out lines FWa to the fourth fan-out line FW4b. The first connecting line FCW1b may be disposed in the sealing area SA and the second and third wiring areas NSA1_b and NSA2_a, and the second connecting line FCW2b may be disposed in the sealing area SA and the second and third wiring areas NSA1_b and NSA2_a. For example, the first and second connecting lines FCW1b and FCW2b may extend from the sealing area SA to the first wiring area NSA1_a through the second wiring area NSA1_b. For example, the first and second connecting lines FCW1b and FCW2b may extend from the sealing area SA to the fourth wiring area NSA2_b through the third wiring area NSA2_a. Accordingly, first and second contact holes FCNT1a and FCNT2a may be positioned in the first wiring area NSA1_a, and third and fourth contact holes FCNT3a and FCNT4a may be positioned in the fourth wiring area NSA2_b. For example, based on the second direction DR2, the width of the area where the first and second connecting lines FCW1b and FCW2b are disposed may be expanded to be greater than the width of the sealing area SA.

According to an embodiment, each of the first and third fan-out lines FW1 and FW3 may be formed in a double-layer wiring structure, and each of the second and fourth fan-out lines FW2 and FW4 may be formed of the second gate wiring layer GAT2 having a low sheet resistance. Accordingly, the overall wiring resistance of the first to fourth fan-out lines FW1 to FW4 may be decreased.

For example, the second gate wiring layer GAT2 including aluminum may not be disposed in the sealing area SA, and thus the second gate wiring layer GAT2 may not overlap the sealant SM in plan view (or when viewed from above the plane). Accordingly, in a laser irradiation process for melting the sealant SM, defects such as a short circuit between the fan-out lines due to aluminum eluted by heat generated by a laser may be prevented.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first substrate including a plurality of pixels disposed in a display region and a fan-out wiring part disposed in a peripheral region adjacent to the display region;
a second substrate facing the first substrate; and
a sealant disposed in a sealing area of the peripheral region, the sealant coupling the first and second substrates, wherein
the fan-out wiring part includes:
a first fan-out line disposed in a first non-sealing area of the peripheral region, the first fan-out line including a first gate wiring layer and a third gate wiring layer disposed on the first gate wiring layer and connected to the first gate wiring layer, the first non-sealing area not overlapping the sealant;
a second fan-out line disposed in the first non-sealing area, the second fan-out line including a second gate wiring layer having a lower sheet resistance than sheet resistances of the first and third gate wiring layers;
a first connecting line disposed in the sealing area and connected to the first fan-out line, the first connecting line including at least one of the first gate wiring layer and the third gate wiring layer; and
a second connecting line disposed in the sealing area and connected to the second fan-out line, the second connecting line including at least one of the first gate wiring layer and the third gate wiring layer.

2. The display device of claim 1, wherein the first, second, and third gate wiring layers are disposed on different insulating layers, respectively.

3. The display device of claim 1, wherein
each of the first and third gate wiring layers is a single-layer, and
the second gate wiring layer is a multi-layer in which a plurality of metal layers are sequentially stacked each other.

4. The display device of claim 3, wherein
at least one of the plurality of metal layers includes aluminum, and
the second gate wiring layer does not overlap the sealant in plan view.

5. The display device of claim 1, wherein the first and second connecting lines include different gate wiring layers.

6. The display device of claim 5, wherein
the first connecting line includes the first gate wiring layer, and
the second connecting line includes the third gate wiring layer.

7. The display device of claim 1, further comprising:
a driver chip mounted on the first substrate, wherein
the first substrate further includes data lines disposed in the display region and connected to the plurality of pixels, and
the fan-out wiring part connects the driver chip and the data lines.

8. The display device of claim 7, wherein
the fan-out wiring part further includes:
a third fan-out line disposed in a second non-sealing area of the peripheral region, the third fan-out line including the first gate wiring layer and the third gate wiring layer, the second non-sealing area not overlapping the sealant and disposed between the sealing area and the driver chip; and
a fourth fan-out line disposed in the second non-sealing area, the fourth fan-out line including the second gate wiring layer.

9. The display device of claim 8, wherein
the third fan-out line is connected to the first connecting line, and
the fourth fan-out line is connected to the second connecting line.

10. The display device of claim 8, wherein
the third fan-out line is connected to the second connecting line, and
the fourth fan-out line is connected to the first connecting line.

11. The display device of claim 7, wherein
the fan-out wiring part further includes:
a third fan-out line disposed in a second non-sealing area of the peripheral region, the third fan-out line including a first data wiring layer, the second non-sealing area not overlapping the sealant and disposed between the sealing area and the driver chip; and
a fourth fan-out line disposed in the second non-sealing area, the fourth fan-out line including a second data wiring layer.

12. The display device of claim 11, wherein the first data wiring layer and the second data wiring layer are disposed on different insulating layers, respectively.

13. The display device of claim 12, wherein the first data wiring layer and the second data wiring layer include a same material.

14. The display device of claim 11, wherein
the first and second data wiring layers have a lower sheet resistance than sheet resistances of the first, second, and third gate wiring layers, and
the third and fourth fan-out lines have a smaller width than widths of the first and second fan-out lines.

15. A display device comprising:
a first substrate including a plurality of pixels disposed in a display region and a fan-out wiring part disposed in a peripheral region adjacent to the display region;
a second substrate facing the first substrate; and
a sealant disposed in a sealing area of the peripheral region, the sealant being coupling the first and second substrates, wherein
the fan-out wiring part includes:
a first fan-out line disposed in a first non-sealing area of the peripheral region, the first fan-out line including one of a second gate wiring layer, a first data wiring layer, and a second data wiring layer, the first non-sealing area not overlapping the sealant and disposed between the sealing area and the display region;
a second fan-out line disposed in the first non-sealing area, the second fan-out line including one of the second gate wiring layer, the first data wiring layer, and the second data wiring layer;
a first connecting line disposed in the sealing area and connected to the first fan-out line, the first connecting line including at least one of a first gate wiring layer and a third gate wiring layer; and
a second connecting line disposed in the sealing area and connected to the second fan-out line, the second connecting line including at least one of the first gate wiring layer and the third gate wiring layer,
the first, second, and third gate wiring layers and the first and second data wiring layers are disposed on different insulating layers, and
the second gate wiring layer and the first and second data wiring layers have a lower sheet resistance than sheet resistances of the first and third gate wiring layers.

16. The display device of claim 15, wherein the first and second connecting lines include different gate wiring layers, respectively.

17. The display device of claim 16, wherein
the first connecting line includes the first gate wiring layer, and
the second connecting line includes the third gate wiring layer.

18. The display device of claim 15, further comprising:
a driver chip mounted on the first substrate, wherein
the first substrate further includes data lines disposed in the display region and connected to the plurality of pixels, and
the fan-out wiring part connects the driver chip and the data lines.

19. The display device of claim 18, wherein the fan-out wiring part further includes:
a third fan-out line disposed in a second non-sealing area of the peripheral region, the third fan-out line including one of the first and second data wiring layers, the second non-sealing area not overlapping the sealant and disposed between the sealing area and the driver chip; and
a fourth fan-out line disposed in the second non-sealing area, the fourth fan-out line including one of the first and second data wiring layers.

20. The display device of claim 19, wherein
each of the first, second, third, and fourth fan-out lines includes the first data wiring layer, and
the first, second, third, and fourth fan-out lines have a smaller width than widths of the first and second connecting lines.
